(19) United States
(12) Patent Application Publication
(10) Pub. No.: US 2009/0126974 A1
(43) Pub. Date: May 21, 2009

(54) Manufacturing Process for a Prepreg with a Carrier, Prepreg with a Carrier, Manufacturing Process for a Thin Double-Sided Plate, Thin Double-Sided Plate and Manufacturing Process for a Multilayer-Printed Circuit Board

(76) Inventors: Maroshi Yuasa, Tokyo (JP); Takeshi Hosomi, Tokyo (JP); Masataka Arai, Tokyo (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/921,461

(22) PCT Filed: Sep. 27, 2006
(86) PCT No.: PCT/JP2006/319193

§ 371 Date: Dec. 3, 2007

(30) Foreign Application Priority Data
Sep. 30, 2005 (JP) 2005-288716
Feb. 13, 2006 (JP) 2006-035408

(51) Int. Cl. B32B 37/02; B32B 5/02; H05K 1/00

(52) U.S. Cl. 174/250; 156/182; 442/59

(57) ABSTRACT

A process for manufacturing a prepreg with a carrier exhibiting excellent impregnating properties and thickness precision, which is particularly suitably used for preparing a build-up type multilayer-printed circuit board is provided. Also, a prepreg with a carrier prepared by the manufacturing process and a process for manufacturing a multilayer-printed circuit board utilizing the prepreg with a carrier are provided. There is provided a process for continuously manufacturing a prepreg with a carrier comprising an insulating resin layer having a backbone material of a textile fabric, (a) laminating the insulating resin layer side of a first and a second carriers comprising an insulating resin layer on one side on the both sides of the textile fabric, respectively, to form a laminate and bonding them under a reduced pressure, and (b) after the bonding, heating the laminate at a temperature equal to or higher than a melting point of the insulating resin.

### TECHNICAL FIELD

The present invention relates to a manufacturing process for a prepreg with a carrier, a prepreg with a carrier, and a manufacturing process for a multilayer-printed circuit board. This invention also relates to a process for manufacturing a thin double-sided plate, a thin double-sided plate, and a process for manufacturing a multilayer-printed circuit board having a thin double-sided plate.

### BACKGROUND ART

Recently, there have been needed high-density, densely mounted, and thinner multilayer-printed circuit boards.

A multilayer-printed circuit board is typically manufactured by a build-up method. In the build-up method, to provide an inner-layer circuit board, a circuit is formed on a metal-foiled laminated plate which is prepared by laminating a prepreg and a metal foil and then pressing the laminate under heating. Then, on both sides of the inner-layer circuit board, an insulating layer, which is so-called build-up materials, and a conductor circuit layer are alternately laminated.

When a multilayer-printed circuit board is of a large size or is mounted with semiconductor components such as a flip chip with a fine pitch, it requires adequate mechanical strength to ensure mounting reliability. It may be achieved by using a thicker inner-layer circuit board, which may, however, lead to a problem of increase in a total thickness of the multilayer-printed circuit board because of increase in the number of layers associated with higher integration and more densified mounting.

Thus, there has been proposed a technique that a prepreg is used as a build-up material for providing mechanical strength by means of the base material of the prepreg to ensure mounting reliability while achieving a thinner inner-layer circuit board (for example, see Japanese Laid-open Patent Publication No. 2004-342871).

A prepreg can be built up on an inner-layer circuit board by laminating the inner-layer circuit board and the prepreg and then pressing the laminate under heating by a flat press for curing, or by compressing an inner-layer circuit board and a prepreg by a roll laminator and then curing the product by a heating/drying apparatus.

In the method using a flat press, a resin during pressing under heating is relatively more flowable, so that the insulating layer in the prepreg tends to change its shape.

On the other hand, the method using a roll laminator can control thickness precision for an insulating layer formed. Thus, a desired insulating layer is easily formed by using the method and the method is advantageously efficient in productivity because it can be continuously conducted. It may be, therefore, effective to use a prepreg excellent in thickness precision and impregnating properties in the method using a roll laminator.

However, in a conventional process for manufacturing a prepreg, for example, a process where a textile fabric base material is immersed in a resin varnish for impregnation and then dried using a typical coater, it is difficult to ensure thickness precision due to tendency to generation of striped irregularity in a coating direction.

To solve the problem, there has been disclosed a process for manufacturing a prepreg with excellent thickness precision wherein an insulating resin with a carrier is laminated on both sides of a textile fabric base material (for example, see Japanese Laid-open Patent Publication No. 2004-123870).

Patent Document 1: Japanese Laid-open Patent Publication No. 2004-342871

Patent Document 2: Japanese Laid-open Patent Publication No. 2004-123870

### DISCLOSURE OF THE INVENTION

A prepreg with excellent thickness precision may be prepared by a process where an insulating resin with a carrier is laminated on both sides of a textile fabric base material.

In the process, the textile fabric base material is, however, insufficiently impregnated with a resin component, often giving a prepreg with residual voids. Thus, when such a prepreg is used in manufacturing a multilayer-printed circuit board, insulation reliability may be deteriorated.

Furthermore, a multilayer-printed circuit board is used, for example, in a substrate for a package on which semiconductor components are mounted. Development in densifying and thinning technique has increased the number of applications of new packages such as BGA, and a substrate for a package has been required to be heat resistant and less thermally expansible. Thus, there has been needed a prepreg capable of endowing the package with such properties.

In view of the background described above, the present invention provides a process for manufacturing a prepreg with a carrier exhibiting excellent impregnating properties and thickness precision, which is particularly suitably used for preparing a build-up type multilayer-printed circuit board, and provides a prepreg with a carrier prepared by the manufacturing process, and a process for manufacturing a multilayer-printed circuit board utilizing the prepreg with a carrier.

The invention also provides a manufacturing process for a thin double-sided plate and a thin double-sided plate prepared by the process. The above objectives can be achieved by the following aspects (1) to (40) of the present invention.

(1) A process for continuously manufacturing a prepreg with carriers comprising an insulating resin layer having a backbone material of a textile fabric,

(a) laminating each insulating resin layer side of a first and a second carriers comprising an insulating resin layer on one side on the both sides of the textile fabric, respectively, to form a laminate and bonding them under a reduced pressure, and

(b) after the bonding, heating the laminate at a temperature equal to or higher than a melting point of the insulating resin.

(2) The process as described in (1), wherein in the step (a), the laminate is bonded by pressing it from both sides with at least a pair of laminate rolls.

(3) The process as described in (2), wherein the insulating resin layer in the laminate is a film.

(4) The process for manufacturing a prepreg with carriers as described in (1), wherein

the first and the second carriers with an insulating resin layer comprise a carrier having a larger dimension than that of the textile fabric in a width direction, and

the first and the second carriers with an insulating resin layer comprise an insulating resin layer having a larger dimension than that of the textile fabric in a width direction.

(5) The process for manufacturing a prepreg with carriers as described in (4), wherein in the step (a),

in the inner region of the dimension in a width direction of the textile fabric, the insulating resin layer sides of the first and the second carriers with an insulating resin layer are bonded to the both sides of the textile fabric, respectively, and

in the outer region of the dimension in a width direction of the textile fabric, the insulating resin layers of the first and the second carriers with an insulating resin layer are bonded each other.

(6) The process for manufacturing a prepreg with carriers as described in (1), wherein

the first and second carriers with an insulating resin layer comprise a carrier having a larger dimension than that of the textile fabric in a width direction, and

the first carrier with an insulating resin layer comprises an insulating resin layer having a larger dimension than that of the textile fabric in a width direction.

(7) The process for manufacturing a prepreg with carriers as described in (6), wherein in the step (a),

in the inner region of the dimension in a width direction of the textile fabric, the insulating resin layer sides of the first and second carriers with an insulating resin layer are bonded to the both sides of the textile fabric, respectively, and

in the outer region of the dimension in a width direction of the textile fabric, the insulating resin layer of the first carrier with an insulating resin layer and the carrier of the second carrier with an insulating resin layer are bonded.

(8) The process for manufacturing a prepreg with carriers as described in any of (1) to (5), wherein the step (a) is conducted using a vacuum laminator.

(9) The process for manufacturing a prepreg with carriers as described in any of (1) to (8), wherein the step (b) is conducted substantially without applying any pressure to the bonded product formed in the step (a).

(10) The process for manufacturing a prepreg with carriers as described in any of (1) to (9), wherein the textile fabric is a glass fabric.

(11) The process for manufacturing a prepreg with carriers as described in any of (1) to (8), wherein the first and/or the second carriers with an insulating resin layer comprise a film sheet whose surface on which the insulating resin layer is to be formed is processed to be peelable.

(12) The process for manufacturing a prepreg with carriers as described in any of (1) to (11), wherein the first and/or the second carriers with an insulating resin layer comprise a metal foil.

(13) The process for manufacturing a prepreg with carriers as described in (1), wherein the insulating resin layer is prepared from a resin composition containing a cyanate resin.

(14) The process for manufacturing a prepreg with carriers as described in (1), wherein the resin composition is prepared from a resin composition containing an epoxy resin.

(15) The process for manufacturing a prepreg with carriers as described in (1), wherein the resin composition is prepared from a resin composition containing a phenol resin.

(16) The process for manufacturing a prepreg with carriers as described in (13), wherein the resin composition is prepared from a resin composition further containing a phenoxy resin.

(17) The process for manufacturing a prepreg with carriers as described in any of (1) to (16), wherein the resin composition further comprises an inorganic filler.

(18) A process for continuously manufacturing a prepreg with carriers comprising an insulating resin layer having a backbone material of a textile fabric,

(a) laminating each insulating resin layer side of a first and a second carriers comprising an insulating resin layer on one side on the both sides of the textile fabric, respectively, to form a laminate and bonding them under a reduced pressure, and

(b) after the bonding, heating the laminate at a temperature equal to or higher than a melting point of the insulating resin;

wherein the insulating resin layer is a film, and in the step (a), the laminate is bonded through pressing on both sides by passing it between at least a pair of laminate rolls.

(19) A prepreg with carriers prepared by the process as described in any of (1) to (18).

(20) A process for manufacturing a multilayer-printed circuit board, comprising

(c) removing at least one carrier of the prepreg with carriers as described in (19), and

(d) laminating the insulating resin layer in the side where the carrier of the prepreg with carriers is removed and an inner-layer circuit board on which a circuit is formed, and then forming the laminate.

(21) The process for manufacturing a multilayer-printed circuit board as described in (20), wherein the step (d) is conducted while a carrier is present in the opposite side to the side of the prepreg with carriers in which a carrier is removed.

(22) A process for continuously manufacturing a thin double-sided plate comprising providing a thin double-sided plate comprising an insulating resin layer containing a backbone material of a textile fabric, wherein the insulating resin layer containing the backbone material of the textile fabric is prepared by impregnating both sides of the backbone material of the textile fabric with a first and a second insulating resin layers, and the first and the second insulating resin layers are an insulating resin layer with a carrier where the carrier is on the opposite side to the side to be impregnated in the backbone material of the textile fabric, and the insulating resin layer containing the backbone material of the textile fabric has a thickness of 50 μm or less.

(23) The process for manufacturing a thin double-sided plate as described in (22), comprising

(a) laminating the insulating resin layer sides of the first and the second insulating resin layers with a carrier and both sides of the backbone material of the textile fabric, respectively, to form a laminate, and then bonding them under a reduced pressure, and

(b) curing, after the bonding, the insulating resin layer comprising the backbone material of the textile fabric by heating to provide a thin double-sided plate.

(24) The process as described in (23), wherein in the step (a), the laminate is bonded by pressing it on both sides with at least a pair of laminate roll.

(25) The process as described in (24), wherein the insulating resin layer of the laminate is a film.

(26) The process for manufacturing a thin double-sided plate as described in any of (22) to (25), wherein the textile fabric is a glass fabric.

(27) The process for manufacturing a thin double-sided plate as described in any of (22) to (26), wherein the textile fabric has a thickness of 48 μm or less.

(28) The process for manufacturing a thin double-sided plate as described in any of (22) to (27), wherein the insulating resin used for the insulating resin layer is comprised of a resin composition containing a thermosetting resin.

(29) The process for manufacturing a thin double-sided plate as described in (28), wherein the resin composition comprises an epoxy resin.

(30) The process for manufacturing a thin double-sided plate as described in (28), wherein the resin composition comprises a phenol resin.

(31) The process for manufacturing a thin double-sided plate as described in (28), wherein the resin composition comprises a phenoxy resin.

(32) The process for manufacturing a thin double-sided plate as described in (28), wherein the resin composition comprises a cyanate resin and/or prepolymer thereof.

(33) The process for manufacturing a thin double-sided plate as described in any of (22) to (32), wherein the resin composition further comprises an inorganic filler.

(34) The process for manufacturing a thin double-sided plate as described in (33), wherein the inorganic filler is silica.

(35) The process for manufacturing a thin double-sided plate as described in (33), wherein a content of the inorganic filler is equal to or more than 30% by weight and equal to or less than 80% by weight based on the total weight of the resin composition.

(36) The process for manufacturing a thin double-sided plate as described in any of (22) to (35), wherein the carrier comprises a metal foil.

(37) The process for manufacturing a thin double-sided plate as described in any of (22) to (36), wherein the carrier comprises a film sheet whose surface on which the insulating resin layer is to be formed is processed to be peelable.

(38) A process for manufacturing a thin double-sided plate,

(a) laminating an insulating resin layer sides of a first and a second insulating resin layers with a carrier and both sides of a backbone material of a textile fabric to form a laminate, and then bonding them under a reduced pressure, and

(b) curing, after the bonding, the insulating resin layer comprising the backbone material of the textile fabric by heating to provide a thin double-sided plate,

wherein the insulating resin layer is a film, and in the step (a), the laminate is bonded through pressing from both sides by passing it between at least a pair of laminate rolls.

(39) A thin double-sided plate prepared by the manufacturing process as described in any of (22) to (38).

(40) A multilayer-printed circuit board comprising the thin double-sided plate as described in (39).

According to the present invention, a prepreg with a carrier having excellent impregnation properties and thickness precision can be readily manufactured. A prepreg with a carrier of the present invention is suitably used for manufacturing a multilayer-printed circuit board which is required to be highly densified and multi-layered.

Furthermore, according to the present invention, a thin double-sided plate can be manufactured. A thin double-sided plate of the present invention is suitably used for manufacturing a multilayer-printed circuit board which is required to be highly densified, multi-layered or thinner.

### BRIEF DESCRIPTION OF THE DRAWINGS

The above and other objectives, features and advantages will be more clearly understood with reference to the suitable embodiments described below and the following accompanied drawings.

FIG. 1 is a schematic view illustrating positional relation of a carrier, a carrier with an insulating resin layer and a textile fabric used in a manufacturing process of the present invention.

FIGS. 2 to 4 are schematic views illustrating configurational examples for various width-directional dimensions of a carrier, an insulating resin layer and a textile fabric used in a manufacturing process of the present invention.

FIG. 5(1) is a schematic sectional side view illustrating an example of a configuration of an apparatus for manufacturing a carrier with an insulating resin layer used in a manufacturing process of the present invention, and FIG. 5(2) is a schematic sectional side view illustrating an example of a configuration of an apparatus for manufacturing a prepreg with a carrier used in a manufacturing process of the present invention.

FIG. 6 is a schematic sectional side view of an apparatus used in Experimental Examples A5 and B9.

FIG. 7 is a schematic view illustrating a configurational example for a width-directional dimension of a carrier, an insulating resin layer and a textile fabric used in a process for manufacturing a thin double-sided plate of the present invention.

### BEST MODE FOR CARRYING OUT THE INVENTION

There will be detailed a process for manufacturing a prepreg with a carrier, a prepreg with a carrier, and a multilayer-printed circuit board according to the present invention.

A process for manufacturing a prepreg with a carrier according to the present invention is a process for continuously manufacturing a prepreg with a carrier comprising an insulating resin layer having a backbone material of a textile fabric, (a) laminating the insulating resin layer sides of a first and a second carriers comprising an insulating resin layer on one side of the carriers, on both sides of the textile fabric, respectively to form a laminate and bonding them under a reduced pressure, and (b) after the bonding, heating the laminate at a temperature equal to or higher than a melting point of the insulating resin.

First, there will be described the step (a).

In the step (a), a first and a second carriers with an insulating resin layer are laminated with a textile fabric and they are bonded under a reduced pressure.

Thus, even when there exist unfilled spaces within the textile fabric or in a bonding region between the insulating resin layer of the carrier with an insulating resin layer and the textile fabric during bonding the carrier with an insulating resin layer and the textile fabric, they can be made low-pressure voids or substantially vacuum voids.

In terms of the vacuuming conditions, the process is preferably conducted under a pressure which is the ambient pressure by 700 Torr or more. The pressure is more preferably lower than the ambient pressure by 740 Torr or more. Thus, the above effects can be more prominent.

There are no particular restrictions to a method for bonding the first and the second carriers with an insulating resin layer and the textile fabric. For example, the textile fabric and the carriers with an insulating resin layer can be bonded while continuously feeding them.

There are no particular restrictions to a procedure for bonding under a reduced pressure. For example, a vacuum laminator and a vacuum box can be used.

Among these, it is preferable to continuously laminate and bond the textile fabric and the carriers with an insulating resin layer using a vacuum laminator. It allows for continuous processing and thus efficient preparation of a prepreg with a carrier using a simple apparatus.

For example, it is preferable to conduct the bonding by laminating the first and second carriers with an insulating resin layer and the textile fabric without an impregnated resin to form a laminate, and by pressing the laminate on both sides while passing it between at least a pair of laminate roll. The use of this procedure allows the textile fabric to be adequately impregnated with the insulating resin layer.

In a preferred aspect, the insulating resin layer is preferably a film in the light of facilitating pressing and bonding using rolls. The layer as a film can facilitate pressing and bonding using the rolls.

In the step (a), during bonding the side of the insulating resin layer in the carriers with the insulating resin layer and the textile fabric, it is preferable to heat them at a temperature at which the insulating resin layer can be melted. Thus, the textile fabric and the insulating resin layer can be easily bonded. Furthermore, at least part of the insulating resin layer is melted and infiltrates into the textile fabric, so that a prepreg with a carrier with good impregnation properties can be easily obtained.

There are no particular restrictions to a heating procedure. For example, a procedure using laminate rolls heated to a given temperature during bonding may be suitably employed.

Here, there are no particular restrictions to a heating temperature because it varies depending on the type and the composition of a resin for forming the insulating resin layer. For example, it may be 60° C. to 100° C.

There will be described a carrier with an insulating resin layer used in the step (a).

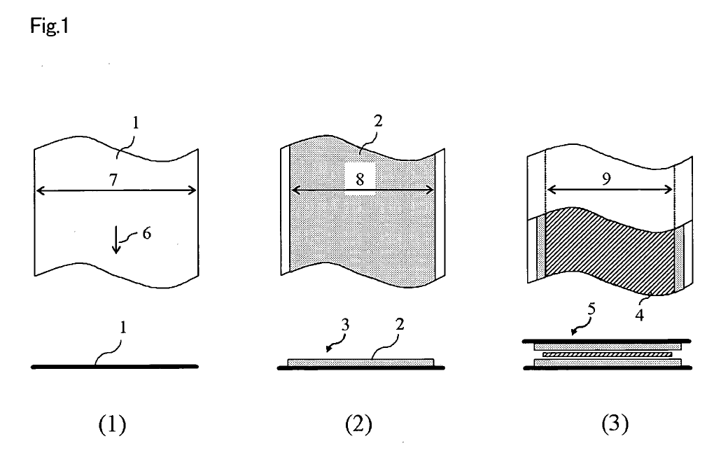

FIG. 1(2) shows an example of a carrier with an insulating resin layer 3 used in the present invention.

A carrier with an insulating resin layer 3 is a carrier 1 in one of whose sides an insulating resin layer 2 is formed as a thin film. The insulating resin layer 2 has a width-directional dimension 8 and can be formed in one side of the carrier 1 with a given thickness. Herein, the width-directional dimension 8 refers to a dimension of the insulating resin layer 2 of the carrier 1 in a direction perpendicular to a feeding direction.

There will be described a carrier used in the carrier with an insulating resin layer described above.

FIG. 1(1) shows an example of the carrier 1 applied to the carrier with an insulating resin layer 3 used in the present invention.

The carrier 1 can be continuously fed to the direction of the arrow 6, and has a width-directional dimension 7. Here, a width-directional dimension 7 refers to a dimension of the carrier 1 in a direction perpendicular to a feeding direction.

Such a carrier 1 may be suitably, for example, a long sheet.

There are no particular restrictions to a material for the above carrier. For example, it may be a thermoplastic resin film sheet made from a thermoplastic resin such as polyethylene terephthalate, polyethylene and a polyimide, or a metal foil made of a metal such as copper or a copper alloy, aluminum or an aluminum alloy, and silver or a silver alloy.

Among these, polyethylene terephthalate is preferable as a thermoplastic resin for forming a thermoplastic resin film sheet because it is highly heat resistant and inexpensive.

As a metal for forming a metal foil, copper or a copper alloy is preferable because it is highly conductive, allows a circuit to be easily formed by etching, and is inexpensive.

When using a thermoplastic resin film sheet as the carrier, it is preferable that a surface of the sheet on which an insulating resin layer is to be formed is processed to be peelable. Thus, the insulating resin layer can be easily separated from the carrier during or after production of a multilayer-printed circuit board.

A thickness of this thermoplastic resin film sheet may be, for example, 25 μm to 75 μm. Thus, workability during preparing a carrier with an insulating resin layer may be improved.

If a thickness of the thermoplastic resin film sheet is too small, mechanical strength may be inadequate during preparing the carrier with an insulating resin layer. If the thickness is too large, there are no problems in preparing the carrier with an insulating resin layer, but productivity in preparing the carrier with an insulating resin layer may be deteriorated.

When using a metal foil as the above carrier, it may be one where a surface of the metal foil on which an insulating resin layer is to be formed is processed to be peelable, or one which is not subjected to such processing or is made more adhesive to the insulating resin layer.

When as the above carrier, a metal foil where a surface of the metal foil on which the insulating resin layer is to be formed is processed to be peelable is used, it may be effective as in the case where the thermoplastic resin film sheet is used.

A thickness of this metal foil may be, for example, 1 μm to 70 μm. Thus, workability during preparing a carrier with an insulating resin layer may be improved.

If a thickness of the metal foil is too small, mechanical strength may be inadequate during preparing the carrier with an insulating resin layer. If the thickness is too large, there are no problems in preparing the carrier with an insulating resin layer, but productivity may be deteriorated.

When as the above carrier a thermoplastic resin film sheet or a metal foil where a surface of the metal foil on which an insulating resin layer is to be formed is processed to be peelable, is used, it is preferable that the surface on which the insulating resin layer is to be formed is as smooth as possible. Thus, when preparing a multilayer-printed circuit board, surface smoothness can be improved in the insulating layer, and a finer circuit can be more easily processed/formed when the surface of the insulating layer is processed to be rough and then an additional conductor layer is formed by, for example, metal plating.

When as the above carrier a metal foil which is unprocessed to be peelable or is made more adhesive to the insulating resin layer, is used, the metal foil as such can be used as a conductor layer for forming a circuit when preparing a multilayer-printed circuit board.

The carrier surface in the side in which the insulating resin layer is to be formed may have irregularity of, for example, Ra: 0.1 μm to 0.5 μm. In this case, adhesiveness between the insulating layer and the metal foil can be adequately ensured, and by processing this metal foil by, for example, etching, a fine circuit may be easily processed/formed.

The metal foil may preferably have a thickness of, for example, 1 μm to 35 μm. If the metal foil has a too small thickness, mechanical strength may be inadequate during preparing a carrier with an insulating resin layer. If the thickness is too large, it may become difficult to process/form a fine circuit.

This metal foil may be used as one carrier of the carries with an insulating resin layer which are used for preparing a prepreg with a carrier, to prepare a prepreg with a carrier. A metal foil used in such an application may be a metal foil formed from one layer or a metal foil consisting of two or more metal foil layers which are peelable from each other. For example, a two-layer structure metal foil may be used, in which a first metal foil in the side where an insulating layer is to be glued is peelably bonded to a second metal foil capable of supporting the first metal foil in the opposite side to the side where the insulating layer is to be glued.

There will be described insulating resin materials for forming the insulating resin layer in the carrier with an insulating resin layer.

Examples of insulating resin materials suitably used for forming an insulating resin layer include, but not limited to, thermosetting resins such as epoxy resins, phenol resins, cyanate resins, unsaturated polyester resins, dicyclopentadiene resins. Particularly, the above insulating resin material preferably contains a cyanate resin. A prepreg with a carrier prepared using a cyanate resin may exhibit improved heat resistance and low-thermal expansion.

In addition, it may contain, if needed, additives such as a curing agent, a curing accelerator, a thermoplastic resin, an inorganic filler, an organic filler and a coupling agent as appropriate.

An insulating resin used in the present invention may be suitably used as a liquid in which the above components are dissolved and/or dispersed in, for example, an organic solvent.

The cyanate resin may be a reaction product between a halocyanide and a phenol or a prepolymer from the product prepared by, for example, heating.

Specific examples of the resin may include bisphenol type cyanate resins such as novolac type cyanate resins, bisphenol-A type cyanate resins, bisphenol-E type cyanate resins and tetramethyl bisphenol-F type cyanate resins.

Among these cyanate resins, a novolac type cyanate resin can be used to further improve heat resistance because of increase in a crosslink density and to impart excellent rigidity to a cured product of the prepreg with a carrier (hereinafter, sometimes simply referred to as a “cured product”) even when using a thin material as a base material of a textile fabric in a backbone material for a prepreg with a carrier, particularly to increase rigidity during heating.

Furthermore, for example, when applying this prepreg with a carrier to a package substrate mounted with a semiconductor component, its connection reliability can be improved.

Furthermore, a novolac type cyanate resin can be used to improve flame resistance of a cured product. It may be because a novolac type cyanate resin contains benzene rings in a higher proportion due to its structure, resulting in tendency to carbonization.

The novolac type cyanate resin described above may be, for example, that represented by the general formula (I) below.

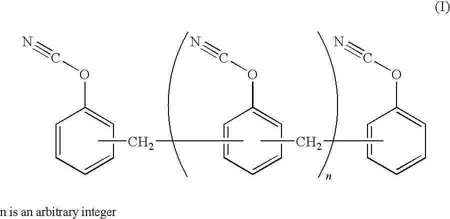

The number “n” of the repeating unit (motif) in the novolac type cyanate resin represented by general formula (I) may be, for example, 1 to 10, suitably 2 to 7.

It may lead to improvement in handling properties of the novolac type cyanate resin and in a crosslink density of a cured product, resulting in good balance between these properties.

If the number “n” is too small, the resin tends to crystallize, which may lead to lower solubility in a common solvent and thus to deterioration in handling properties. On the other hand, if the number “n” is too large, a cured product has an excessively high crosslink density, which may lead to deterioration in water resistance and a brittle cured product.

The above cyanate resin may have a molecular weight of, for example, 500 to 4,500 as a weight average molecular weight (Mw), particularly suitably 600 to 3,000.

Thus, handling properties in preparing a prepreg with a carrier, formability during preparing a multilayer-printed circuit board and interlayer peeling strength can be improved, resulting in good balance between these properties.

If the above Mw is too small, a prepreg with a carrier prepared may be tacky, leading to deterioration in handling properties. If the above Mw is too large, a reaction rate may be increased, leading to defective molding in manufacturing a multilayer-printed circuit board and/or reduction in interlayer peeling strength.

The above cyanate resin is preferably one having a Mw within the above range or two or more of those having different Mws.

An Mw of the above cyanate resin can be determined by, for example, GPC (gel permeation chromatography).

A content of the above cyanate resin is preferably 5 to 50% by weight, particularly preferably 10 to 40% by weight to the total amount of the resin composition.

Thus, a resin layer in a carrier with an insulating resin layer can be easily formed and mechanical strength of a cured product can be improved to achieve good balance between these properties.

If a content of the cyanate resin is too small, it may be difficult to form an insulating resin layer in a carrier with an insulating resin layer. If a content of the cyanate resin is too large, mechanical strength of a cured product may be inadequate.

A resin composition may contain an epoxy resin (containing substantially no halogen atoms).

Examples of an epoxy resin include phenol novolac type epoxy resins, cresol novolac type epoxy resins, bisphenol type epoxy resins, naphthalene type epoxy resins and arylalkylene type epoxy resins.

Among these, an arylalkylene type epoxy resin is preferable. Thus, a cured product can have improved solder heat resistance after humidification.

As used herein, the term “arylalkylene type epoxy resin” refers to an epoxy resin with one or more arylalkylene groups in a motif: for example, xylylene type epoxy resins and biphenyldimethylene type epoxy resins.

Among these, a biphenyldimethylene type epoxy resin is preferable. A biphenyldimethylene type epoxy resin can be represented by, for example, general formula (II).

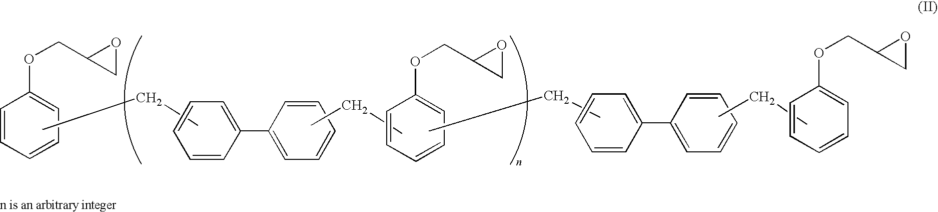

The number “n” of the motif in the biphenyldimethylene type epoxy resin represented by the general formula (II) above may be, for example, 1 to 10, particularly suitably 2 to 5.

It may lead to improvement in handling properties of the biphenyldimethylene type epoxy resin and in moldability in preparing a multilayer-printed circuit board, resulting in good balance between these properties.

If the number “n” is too small, the resin tends to crystallize, which may lead to lower solubility in a common solvent and thus to deterioration in handling properties. On the other hand, if the number “n” is too large, flowability may be reduced, and thus defective molding may be caused in preparing a multilayer-printed circuit board using the prepreg with a carrier.

A content of the epoxy resin may be, for example, 1 to 55% by weight, particularly preferably 2 to 40% by weight to the total amount of the resin composition.

When using an epoxy resin in combination with a cyanate resin, a content in the above range may allow reactivity of a cyanate resin and various properties of a cured product to be improved, resulting in good balance between these properties. If a content of the epoxy resin is too small, a cyanate resin may be inadequately reactive or moisture resistance of a cured product may be reduced. If a content of the epoxy resin is too large, heat resistance of a cured product may be inadequate.

The epoxy resin has a molecular weight of, for example, 500 to 20,000, particularly suitably 800 to 15,000 as a weight average molecular weight (Mw).

Thus, handling properties in preparation of a prepreg with a carrier and its impregnation into a textile fabric base material can be improved, resulting in good balance between these properties.

If the above Mw is too small, a prepreg with a carrier prepared may be tacky, leading to deterioration in handling properties. If the above Mw is too large, impregnation into the textile fabric base material may be reduced.

The above epoxy resin is preferably one having a Mw within the above range or two or more of those having different Mws.

An Mw of the epoxy resin may be determined by, for example, GPC.

A resin composition may contain a phenol resin.

Examples of the phenol resin may include novolac type phenol resins, resol type phenol resins and arylalkylene type phenol resins.

Among these, an arylalkylene type phenol resin is preferable. Thus, a cured product can have further improved solder heat resistance after humidification.

Examples of the arylalkylene type phenol resin may include xylylene type phenol resins and biphenyldimethylene type phenol resins.

Among these, a biphenyldimethylene type phenol resin is preferable. The biphenyldimethylene type phenol resin can be represented by, for example, the general formula (III) below.

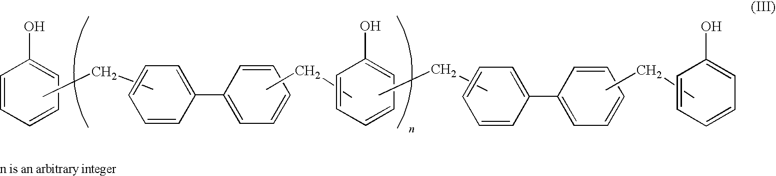

The number “n” of the motif in the biphenyldimethylene type phenol resin represented by the general formula (III) above may be, for example, 1 to 12, particularly suitably 2 to 8.

Thus, its compatibility to other resin components and heat resistance of the cured product can be improved, resulting in good balance between these properties.

If the number “n” is too small, heat resistance of the cured product may be deteriorated. If the number “n” is too large, its compatibility to other resin components may be deteriorated, leading to lower workability.

A content of the phenol resin may be, for example 1 to 55% by weight, particularly preferably 5 to 40% by weight to the total amount of the resin composition.

Thus, the cured product can have improved heat resistance and lower thermal expansion, resulting in good balance between these properties.

If a content of the phenol resin is too low, heat resistance of the cured product may be deteriorated. If a content of the phenol resin is too high, a cured product may have inadequate property of low thermal expansion.

The phenol resin may have a molecular weight of, for example, 400 to 18,000, particularly suitably 500 to 15,000 as a weight average molecular weight (Mw).

Thus, handling properties in preparing a prepreg with a carrier and impregnation properties into a textile fabric base material can be improved, resulting in good balance between these properties.

If the above Mw is too small, a prepreg with a carrier prepared may be tacky, leading to deterioration in handling properties. If the above Mw is too large, impregnation into the textile fabric base material may be reduced.

The above phenol resin is preferably one having a Mw within the above range or two or more of those having different Mws.

An Mw of the phenol resin may be determined by, for example, GPC.

The resin composition may contain a phenoxy resin in combination with the cyanate resin (particularly a novolac type cyanate resin), or in combination with the cyanate resin (particularly, a novolac type cyanate resin) and an epoxy resin.

Thus, deposition properties in preparing a carrier with an insulating resin layer may be improved.

Examples of the phenoxy resin may include phenoxy resins having a bisphenol skeleton, phenoxy resins having a novolac skeleton, phenoxy resins having a naphthalene skeleton and phenoxy resins having a biphenyl skeleton. A phenoxy resin having a structure containing two or more of these skeletons.

Among these, those having both biphenyl and bisphenol-S skeletons can be used. Thus, rigidity of the biphenyl skeleton can increase a glass transition temperature, and the bisphenol-S skeleton can improve adhesiveness of a plated metal in preparing a multilayer-printed circuit board.

A resin having both bisphenol-A and bisphenol-F skeletons may be used. Thus, its adhesiveness to an inner-layer circuit board can be improved in preparing a multilayer-printed circuit board.

The resin having a biphenyl skeleton and a bisphenol-S skeleton can be combined with a resin having a bisphenol-A and a bisphenol-F skeletons. Thus, these properties can be well balanced.

When using the resin (1) having a bisphenol-A and a bisphenol-F skeletons in combination with the resin (2) having a biphenyl and a bisphenol-S skeletons, there are no particular restrictions to a combination ratio, but, for example, it may be (1):(2)=2:8 to 9:1.

A molecular weight of the phenoxy resin may be, but not limited to, 5,000 to 70,000 as a weight average molecular weight.

Thus, improvement effects in deposition properties can be sufficiently achieved in preparing a carrier with an insulating resin layer, and solubility of a phenoxy resin in preparing a resin composition can be improved, resulting in good balance between these properties.

If a weight average molecular weight of the phenoxy resin is too small, the phenoxy resin may be sometimes inadequately effective for improving deposition properties. If the weight average molecular weight is too large, solubility of the phenoxy resin in the resin composition may be deteriorated.

A content of the phenoxy resin may be, for example, 1 to 40% by weight, particularly preferably 5 to 30% by weight to the total amount of the resin composition.

Thus, improvement effects in deposition properties can be sufficiently achieved in preparing a carrier with an insulating resin layer, and lower thermal expansion may be achieved, resulting in good balance between these properties.

If a content of the phenoxy resin is too small, the phenoxy resin may be sometimes inadequately effective for improving deposition properties. If the content is too large, a content of the cyanate resin is correspondingly reduced, leading to insufficient effect of low thermal expansion.

The above resin compositions may be used alone or in combination of two or more. When using the above cyanate resin (particularly, a novolac type cyanate resin) in combination with the above phenol resin (an arylalkylene type phenol resin, particularly a biphenyldimethylene type phenol resin), a crosslink density of the resin components can be controlled, and adhesiveness of an insulating layer to a conductor metal can be improved in preparing a multilayer-printed circuit board using a prepreg with a carrier of the present invention.

When using the above cyanate resin (particularly, a novolac type cyanate resin) in combination with the above epoxy resin (an arylalkylene type epoxy resin, particularly a biphenyldimethylene type epoxy resin) and the above phenol resin (an arylalkylene type phenol resin, particularly a biphenyldimethylene type phenol resin), dimensional stability of a multilayer-printed circuit board can be, in addition to the above effects, particularly improved.

By using the cyanate resin (particularly, a novolac type cyanate resin) in combination with the above epoxy resin (an arylalkylene type epoxy resin, particularly a biphenyldimethylene type epoxy resin) and a phenoxy resin (particularly, a phenoxy resin having a biphenyl and a bisphenol-S skeletons), a glass transition temperature may be, in addition to the above effects, increased, and deposition properties in preparing a carrier with an insulating resin layer can be improved, resulting in good handling properties.

A resin composition may contain, in addition to the resin components described above, an inorganic filler.

Thus, when applying it to a thinner prepreg with a carrier containing a thin textile fabric, mechanical strength of the cured product can be sufficient and lower thermal expansion can be further improved.

Examples of the above inorganic filler may include talc, alumina, glass, silica and mica.

Among these, silica is preferable, and specifically, fused silica is preferable because it is excellent in lower thermal expansion.

A shape of fused silica may be, for example, crushed or spherical, and in particular, spherical fused silica can be used to reduce a melt viscosity of a resin composition. Thus, its impregnation properties into a textile fabric base material can be improved.

An average particle size of the inorganic filler may be, for example, 0.01 to 5.0 μm, particularly suitably 0.2 to 2.0 μm.

Thus, workability in preparing a liquid resin composition can be improved.

If the above average particle size is too small, workability in preparing a liquid resin composition where a resin composition is dissolved and/or disperse in, for example, an organic solvent, may be affected due to increase in its viscosity. If the above average particle size is too large, the inorganic filler may be precipitated in the liquid resin composition.

The above inorganic fillers preferably having an average particle size within the above range may be used alone or in combination of two or more of those having different average particle sizes.

This average particle size can be determined by, for example, particle size distribution measuring apparatus (HORIBA, Ltd.; “LA-500”)

The above inorganic filler is preferably spherical fused silica having an average particle size of 0.01 to 5.0 μm, particularly spherical fused silica having an average particle size of 0.2 to 2.0 μm.

Thus, a filling degree of an inorganic filler in the resin composition can be improved.

A content of the inorganic filler may be, for example, 30 to 80% by weight, preferably 40 to 70% by weight to the total amount of the resin composition.

Thus, the above effects of adding the inorganic filler, particularly lower thermal expansion, can be improved. Furthermore, since the cured product can be less water-absorptive, solder heat resistance after humidification can be improved.

A resin composition used in the preset invention preferably contains a coupling agent, particularly when it contains the above inorganic filler.

This coupling agent can improve wettability in an interface between a resin component such as a cyanate resin and an inorganic filler. Thus, it allows the resin component and the inorganic filler to be evenly settled on a textile fabric, resulting in improvement of heat resistance of the cured product, particularly solder heat resistance after water absorption.

The coupling agent may be any of those commonly used, and for example, it is preferable to use one or more coupling agents selected from epoxysilane coupling agents, titanate coupling agents, aminosilane coupling agents and silicone oil type coupling agents. Thus, wettability described above can be improved and heat resistance of the cured product can be, therefore, further improved.

When using a coupling agent, its content is, for example, 0.05 to 3 parts by weight, particularly preferably 0.1 to 2 parts by weight to 100 parts by weight of the above inorganic filler.

Thus, coating of the inorganic filler can be sufficiently effective and properties of the cured product can be improved, resulting in good balance between these properties.

If a content of the coupling agent is too small, coating of the inorganic filler may be inadequately effective. If a content of the coupling agent is too large, it may affect a reaction of the resin components, leading to deterioration in mechanical strength of the cured product.

A resin composition used in the present invention may, as necessary, further contain a curing accelerator.

The curing accelerator may be any of those known in the art, which may include organometallic salts such as zinc naphthenate, cobalt naphthenate, tin octylate, cobalt octylate, cobalt (II) bisacetylacetonate and cobalt (III) trisacetylacetonate; tertiary amines such as triethylamine, tributylamine and diazabicyclo[2,2,2]octane; imidazoles such as 2-phenyl-4-methylimidazole, 2-phenyl-4-methyl-5-hydroxymethylimidazole, 2-phenyl-4,5-dihydroxymethyl imidazole, 2,4-diamino-6-[2′-methylimidazolyl-(1′)]-ethyl-s-triazine, 2,4-diamino-6-(2′-undecylimidazolyl)-ethyl-s-triazine, 2,4-diamino-6-[2′-ethyl-4-methyl imidazolyl-(1′)]-ethyl-s-triazine and 1-benzyl-2-phenylimidazole; phenols such as phenol, bisphenol-A and nonylphenol; organic acids such as acetic acid, benzoic acid, salicylic acid and para-toluenesulfonic acid; and their mixtures.

Among these, an imidazole compound can be suitably used as a curing accelerator when using a resin composition containing a cyanate resin, an epoxy resin and a phenoxy resin. Thus, a reaction of the cyanate resin or the epoxy resin can be accelerated without deterioration in insulation performance of a resin composition.

The imidazole compound is preferably an imidazole compound having two or more functional groups selected from an aliphatic hydrocarbon, aromatic hydrocarbon, hydroxyalkyl and cyanoalkyl, particularly preferably 2-phenyl-4,5-dihydroxymethyl imidazole. Such an imidazole compound can be used to improve heat resistance of a resin composition and to impart lower thermal expansion and lower water absorptivity to a multilayer-printed circuit board.

When using the above curing accelerator, its content may be, for example, 0.05 to 5% by weight, particularly preferably 0.2 to 2% by weight to the total amount of the resin composition.

Thus, curing of the resin composition can be accelerated and storage stability of a prepreg with a carrier can be improved, resulting in good balance between these properties.

If a content of the curing accelerator is too small, its accelerating effects may be inadequate. If a content of the curing accelerator is too large, storage stability of a prepreg with a carrier may be deteriorated.

A resin composition used in the present invention may additionally contain a thermoplastic resin such as polyimide resins, polyamide-imide resin, polyphenylene oxide resins and polyether sulfone resins.

It may, if necessary, further contain additives other than those described above such as pigments and antioxidants.

In the present invention, a resin composition consisting of the above components may be used in a form of a liquid resin composition dissolved and/or dispersed in, for example, an organic solvent. Thus, an insulating resin layer in a carrier with an insulating resin layer can be conveniently formed.

There will be described the above carrier with an insulating resin layer.

A carrier with an insulating resin layer used in the present invention has an insulating resin layer made from the above insulating resin material on one side of the carrier. The layer can be formed by, but not limited to, applying a liquid insulating resin a carrier using any of various coaters such as a comma coater and a knife coater, or applying a liquid insulating resin on a carrier using any of various spraying devices such as a spray nozzle.

Among these, it is preferable to apply a liquid insulating resin on a carrier using any of various coaters. Thus, a convenient apparatus can be used to form an insulating resin layer with excellent thickness precision.

When preparing a carrier with an insulating resin layer, a liquid insulating resin can be applied on a carrier, which can be, if necessary, then dried at an ambient temperature or under heating.

Thus, when using an organic solvent or dispersion medium for preparing a liquid insulating resin, it can be substantially removed to make the surface of the insulating resin layer non-tacky, giving a carrier with an insulating resin layer with excellent handling properties.

Alternatively, after partly curing the insulating resin, fluidity of the insulating resin in step (a) or step (b) described below can be adjusted.

There are no particular restrictions to the drying method under heating; for example, continuous processing using a hot air oven or infrared heater may be suitably applied.

In a carrier with an insulating resin layer used in the present invention, a thickness of the insulating resin layer may be appropriately selected, depending on a thickness of a textile fabric used. For example, it may be 5 to 100 μm.

This insulating resin layer may be formed by applying the same insulating resin once or more, or applying different insulating resins twice or more.

After thus forming a carrier with an insulating resin layer, a protecting film can be laminated on the upper surface of the insulating resin layer formed, that is, the opposite side to that having a carrier for protecting the surface of the insulating resin layer.

There will be described a configuration for laminating a carrier with an insulating resin layer and a textile fabric.

FIG. 1(3) shows an example of configuration 5 for laminating a carrier with an insulating resin layer 3 and a textile fabric 4.

The textile fabric 4 can be continuously fed/carried in the same direction as the carrying direction of a carrier 1 and has a width-directional dimension 9. Here, the width-directional dimension 9 refers to a dimension of the textile fabric 4 in a direction perpendicular to a feeding direction of the textile fabric 4. Such a textile fabric 4 may be, for example, suitably a long sheet.

Examples of a material for the above textile fabric include, but not limited to, textile fabrics such as woven glass fabric and unwoven glass fabric; inorganic textile fabrics such as woven and unwoven fabrics containing an inorganic compound other than glass as a component; and organic textile fabrics such as aromatic polyamide resins, polyamide resins, aromatic polyester resins, polyester resins, polyimide resins and fluororesins.

Among these, a glass fabric which is a glass textile fabric, can be used to improve mechanical strength and heat resistance of a multilayer-printed circuit board.

When using a glass fabric as the above textile fabric, it may have a thickness of, for example, 15 to 180 μm. Its grammage (a weight of a textile fabric per 1 m²) may be, for example, 17 to 209 g/m².

In a manufacturing process of the present invention, particularly, a thin glass fabric with a thickness of 15 to 35 μm and a grammage of 17 to 25 g/cm² can be used. Even when using such a glass fabric, a prepreg with a carrier exhibiting excellent mechanical properties and impregnating properties can be obtained because fiber bundles constituting the textile fabric is resistant to bending.

A conventional process for manufacturing a prepreg, for example, a process where a textile fabric is immersed in a resin varnish for impregnation and then dried using a common applicator, has a problem that during passing it through a number of carrying rolls or adjusting the amount of the insulating resin impregnated in the textile fabric, the textile fabric tends to be subjected to stress.

The effect is prominent particularly when a thin glass fabric is used; specifically, tendency to bending of the fiber bundles or expansion of an opening between warps and woofs. Such a prepreg has internal strain, which may cause warpage of a multilayer-printed circuit board and affect its mechanical properties such as dimensional stability, and a local defection of resin filling in an enlarged opening, which may cause deterioration in moldability of a multilayer-printed circuit board.

In contrast, in a process for manufacturing a prepreg with a carrier of the present invention, a textile fabric is not substantially subjected to a stress irrespective of a thickness or grammage of a textile fabric. Thus, fiber bundles are resistant to bending and excellent in impregnation properties. Thus, the use of this prepreg with a carrier is advantageous in that it can provide a multilayer-printed circuit board having excellent mechanical properties and moldability. When using a cyanate resin as an insulating resin, it is further advantageous in that it provides a multilayer-printed circuit board further having excellent heat resistance and lower thermal expansion.

In the step (a), two carriers with an insulating resin layer 3 are used. These are called a first carrier with an insulating resin layer and a second carrier with an insulating resin layer, respectively.

Then, the insulating resin layer sides of the first and the second carriers with an insulating resin layer are laminated with both sides of a textile fabric 4 which is not yet impregnated with a resin, respectively.

The first and the second carriers with an insulating resin layer used in the step (a) may be made of the same material or different materials.

There will be described the step (b).

This step (b) contains laminating the insulating resin layer sides of carriers with an insulating resin layer with both sides of a textile fabric base material, and after the lamination, heating it at a temperature equal to or higher than the melting temperature of the insulating resin.

Thus, low-pressure voids or substantially vacuum voids remaining after laminating the carriers with an insulating resin layer with the textile fabric in the step (a) can be eliminated to provide a prepreg with carriers having a very few unfilled parts or substantially free from an unfilled part.

The above heating may be conducted, for example, using an apparatus including, but not limited to, a hot air oven, an infrared heater, a heating roller and a flat hot-plate press.

When using a hot air oven or infrared heater, heating can be conducted substantially without applying a pressure to the above laminate.

When using a heating roller or flat hot-plate press, heating can be conducted with applying a given pressure to the above laminate.

Among these, heating is preferably conducted substantially without applying a pressure to the laminate.

According to this process, the resin components do not excessively flow in the step (b). Thus, a prepreg with a carrier having a desirable and highly even insulating-layer thickness can be efficiently prepared.

As the resin components flow, a stress to the textile fabric base material can be minimized, resulting in a very small internal strain.

Furthermore, a pressure is not substantially applied when the resin components are fused, so that defective dents can be substantially eliminated in this step.

A temperature during the above heating is preferably within a range where an insulating resin used is fused and a curing reaction of the insulating resin does not rapidly proceed.

There are no particular restrictions to a heating time, which depends on factors such as the type of an insulating resin used. For example, the heating can be conducted for 1 to 10 min.

In a manufacturing process of the present invention, a carrier, an insulating resin layer and a textile fabric are used. There will be described a relation in a width-directional dimension for these elements with reference to their specific configurations.

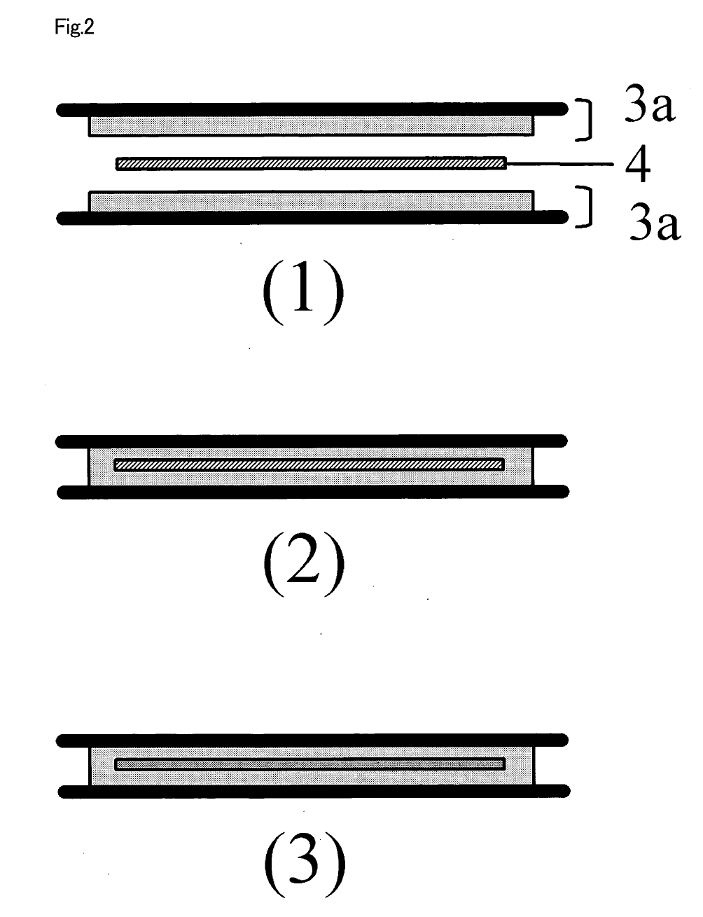

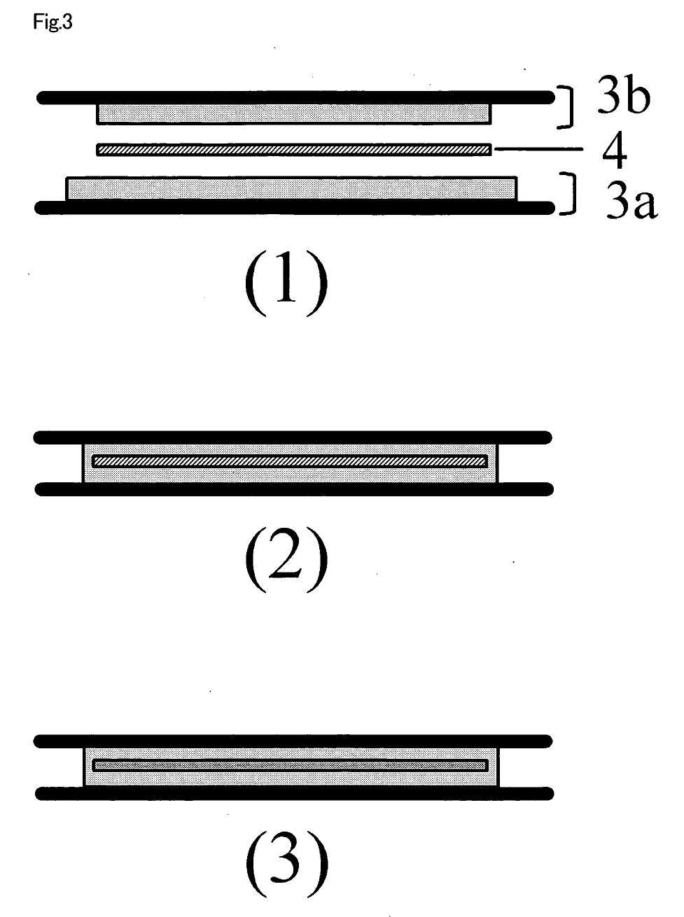

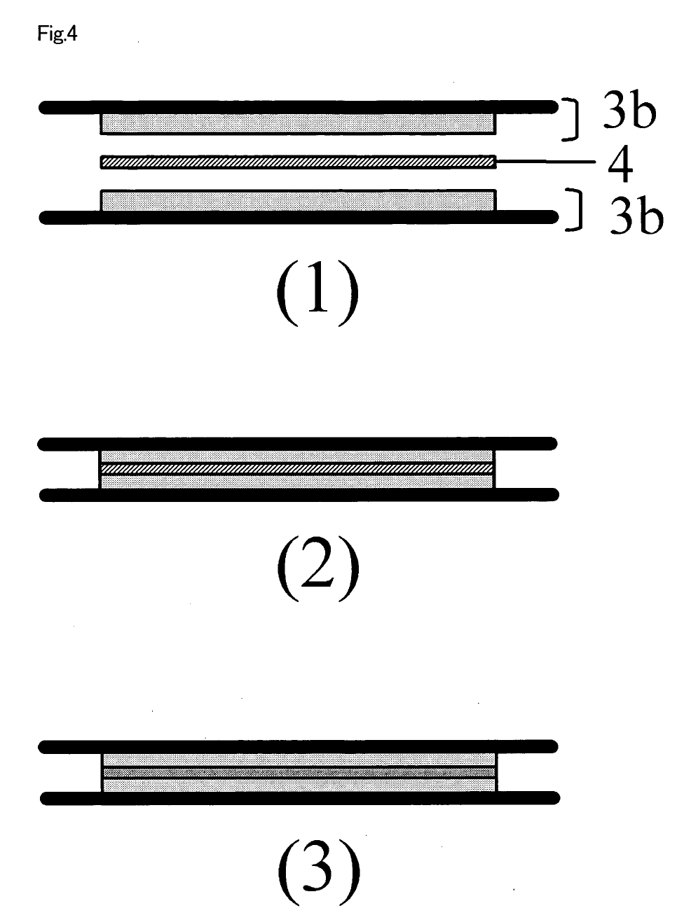

In a manufacturing process of the present invention, a carrier, an insulating resin layer and a textile fabric may be used in various width-directional dimensions, for example, as illustrated in FIG. 2(1) to (3), FIG. 3(1) to (3) and FIG. 4(1) to (3).

First, the configuration shown in FIG. 2(1) to (3) will be described.

In FIG. 2(1) to (3), the first carrier with an insulating resin layer 3a and the second carrier with an insulating resin layer 3a have a carrier having a width-directional dimension larger than that of the textile fabric 4 and an insulating resin layer having a width-directional dimension larger than that of the textile fabric 4. Here, FIG. 2(1) shows relation in a width-directional dimension for each of a carrier, an insulating resin layer and a textile fabric.

In this configuration, in the step (a), the insulating resin layer of the first carrier with an insulating resin layer 3a and the textile fabric 4, and the insulating resin layer of the second carrier with an insulating resin layer 3a and the textile fabric 4, respectively, may be laminated in the inner region of the textile fabric 4 in a width-directional dimension, that is, a region where the textile fabric 4 is present in the width direction.

In the outer region of the textile fabric 4 in the width-directional dimension, that is, a region where the textile fabric is absent, the insulating resin layer surface in the first carrier with an insulating resin layer 3a and the insulating resin layer surface in the second carrier with an insulating resin layer 3a can be directly bonded. The configuration is illustrated in FIG. 2(2).

Furthermore, since these bonding are conducted under a reduced pressure, remaining unfilled parts, if present, within the textile fabric 4 or the bonded surface between the insulating resin layer of the first and the second carriers with an insulating resin layer 3a, 3a and the textile fabric 4 can be made low-pressure voids or substantially vacuum voids. Thus, in the step (b), heating at a temperature equal to or higher than the melting temperature of the resin can easily eliminate them. Furthermore, in the step (b), new void formation due to the air entering from the periphery in the width direction can be prevented. The configuration is illustrated in FIG. 2(3).

There will be described the configuration illustrated in FIG. 3(1) to (3).

In FIG. 3(1) to (3), the first carrier with an insulating resin layer and the second carrier with an insulating resin layer have a carrier having a width-directional dimension larger than that of the textile fabric 4, and one of the two carriers with an insulating resin layer, for example, the first carrier with an insulating resin layer 3a has an insulating resin layer having a width-directional dimension larger than that of the textile fabric 4 while the second carrier with an insulating resin layer 3b has an insulating resin layer having a width-directional dimension equal to that of the textile fabric 4. FIG. 3(1) shows relation in the width-directional dimension for the carrier, the insulating resin layer and the textile fabric.

In this configuration, in the step (a), the insulating resin layer of the first carrier with an insulating resin layer 3a and the textile fabric 4, and the insulating resin layer of the second carrier with an insulating resin layer 3b and the textile fabric 4, respectively, may be laminated in the inner region of the textile fabric 4, that is, a region where the textile fabric 4 is present in the width direction.

In the outer region of the textile fabric 4 in the width-directional dimension, that is, a region where the textile fabric is absent, the insulating resin layer surface in the first carrier with an insulating resin layer 3a and the carrier surface in the second carrier with an insulating resin layer 3b can be directly bonded. The status is illustrated in FIG. 3(2).

Furthermore, since these bonding are conducted under a reduced pressure, remaining unfilled parts, if present, within the textile fabric 4 or the bonded surface between the insulating resin layer of the first and the second carriers with an insulating resin layer 3a, 3b and the textile fabric 4 can be made low-pressure voids or substantially vacuum voids. Thus, in the step (b), heating at a temperature equal to or higher than the melting temperature of the resin can easily eliminate them. Furthermore, in the step (b), new void formation due to the air entering from the periphery in the width direction can be prevented. The configuration is illustrated in FIG. 3(3).

There will be described the configuration illustrated in FIG. 4(1) to (3).

In FIG. 4(1) to (3), the first carrier with an insulating resin layer 3b and the second carrier with an insulating resin layer 3b has an insulating resin layer having a width-directional dimension equal to that of the textile fabric 4. Here, FIG. 4(1) shows relation in a width-directional dimension for each of a carrier, an insulating resin layer and a textile fabric.

In this configuration, in the step (a), the insulating resin layer of the first carrier with an insulating resin layer 3b and the textile fabric 4, and the insulating resin layer of the second carrier with an insulating resin layer 3b and the textile fabric 4, respectively, may be laminated in the inner region of the textile fabric 4, that is, a region where the textile fabric 4 is present in the width direction. This configuration is illustrated in FIG. 4(2).

In this configuration, it is preferable that after the step (a), that is, after the first and the second carriers with an insulating resin layer 3b, 3b are laminated with the textile fabric 4, unfilled parts present in the end in a width direction are not communicated with unfilled parts present in an area other than the end in the width direction.

Thus, the unfilled parts present in the area other than the end in the width direction can be made low-pressure voids or substantially vacuum voids because the step (a) is conducted under a reduced pressure, and they can be easily eliminated by heating at a temperature equal to or higher than the melting temperature of the resin in the step (b). In step (b), new void formation due to the air entering from the periphery in the width direction can be restricted to the end in the width direction. This configuration is illustrated in FIG. 4(3).

In a process for manufacturing a prepreg with a carrier of the present invention, the configuration illustrated in FIG. 2(1) to (3) or FIG. 3(1) to (3) is preferable among the above configurations. That is, it is preferable that the first carrier with an insulating resin layer and the second carrier with an insulating resin layer have a carrier having a width-directional dimension larger than that of the textile fabric, and either or both of the carriers with an insulating resin layer have an insulating resin layer having a width-directional dimension larger than that of the textile fabric.

Thus, in the step (a), the textile fabric can be sealed by the insulating resin layer, so that there can be provided a prepreg with a carrier having few voids or substantially free from voids in the overall region where the textile fabric is present.

In particular, it is preferable to use the configuration illustrated in FIG. 2(1) to (3), where the first carrier with an insulating resin layer 3a and the second carrier with an insulating resin layer 3a have a carrier having a width-directional dimension larger than that of the textile fabric 4 and have an insulating resin layer having a width-directional dimension larger than that of the textile fabric 4.

In this configuration, in the outer region of the textile fabric 4 in the width-directional dimension, both carriers with an insulating resin layer have an insulating resin layer, so that the textile fabric 4 can be more conveniently sealed by the insulating resin layer, resulting in more effectively bringing about the above effects.

In a process for manufacturing a prepreg with a carrier of the present invention, after the step (b), the step of continuously winding up the prepreg with a carrier prepared above may be conducted, if necessary.

Thus, the prepreg with a carrier may be provided as a roll, and this prepreg with a carrier can be used to improve workability in preparing, for example, a multilayer-printed circuit board.

There will be described a suitable embodiment of an apparatus for manufacturing a prepreg with a carrier of the present invention with reference to the drawings.

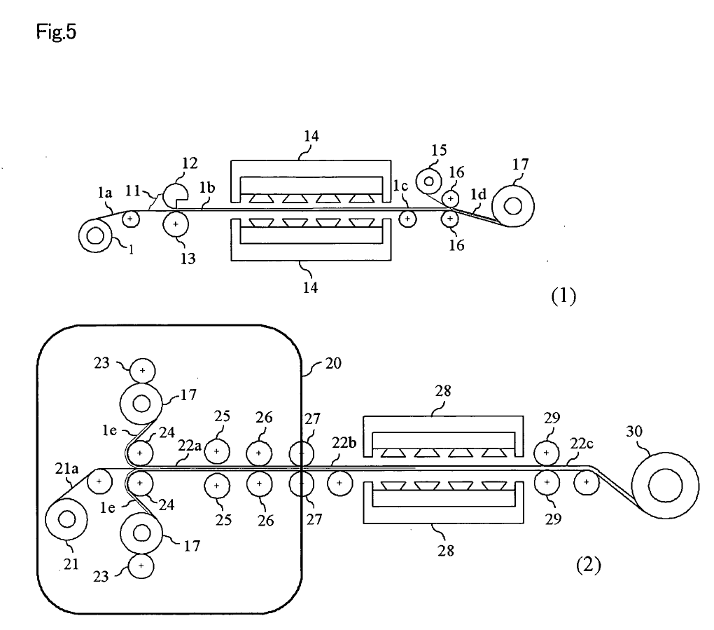

FIG. 5 is a sectional side view illustrating an example of an apparatus to which a manufacturing process of the present invention can be applied.

FIG. 5(1) shows an example of an embodiment of preparing a carrier with an insulating resin layer used for preparation of a prepreg with a carrier of the present invention.

In FIG. 5(1), a carrier 1a may be, for example, a roll of a long sheet, from which it can be continuously winded off for feeding. A liquid insulating resin 11 is continuously fed in a given rate on the carrier 1a by an unshown feeding device of an insulating resin. A coating amount of the insulating resin 11 can be controlled by a clearance of a comma roll 12 and a backup roll 13 of the comma roll 12 to.

A carrier 1b coated with a given amount of the insulating resin can be fed through the inside of a transverse-conveying hot air oven 14, 14 for substantially removing, for example, an organic solvent in a liquid insulating resin to provide a carrier with an insulating resin layer 1c, in which, if necessary, a curing reaction partially proceeds. In a preferable embodiment, the insulating resin layer thus formed in the carrier with an insulating resin layer may be a film.

The carrier with an insulating resin layer 1c can be directly winded up. However, in the embodiment in FIG. 5(1), laminate rolls 16, 16 are used to laminate a protecting film 15 with the side having the insulating resin layer, providing a carrier with an insulating resin layer 1d laminated with the protecting film 15, which is then winded up to give a roll of a carrier with an insulating resin layer 17.

FIG. 5(2) is a sectional side view illustrating an example of an apparatus by which the steps (a) to (b) in the manufacturing process of the present invention can be conducted. Specifically, it shows an embodiment where the insulating resin layer sides of carries with an insulating resin layer are laminated to both sides of a textile fabric which is not yet impregnated with a resin, then the laminate is bonded under a reduced pressure, heated at a temperature equal to or higher than the melting temperature of the insulating resin, and continuously winded up to provide a prepreg with a carrier.

In FIG. 5(2), the step (a) is conducted using a vacuum laminator 20.

The inside of the vacuum laminator 20 is under given vacuum conditions by unshown vacuuming means such as a vacuum pump.

Within the vacuum laminator 20, there are placed the carriers with an insulating resin layer 17, 17 obtained in the above step (a) and the textile fabric 21, each of which can be continuously fed.

The protecting film is laminated on the surface of the insulating resin layer. Thus, the carriers with an insulating resin layer 17, 17 are continuously fed by wind-up rolls 23 while the protecting film is peeled off (1e, 1e). A textile fabric 21a is continuously fed from the roll type textile fabric 21.

After the protecting film is peeled off, the carriers with an insulating resin layer 1e, 1e and the textile fabric 21a are laminated such that the textile fabric 21a is sandwiched between the insulating resin layer sides of the carriers with an insulating resin layer 1e, 1e, and they are bonded by the laminate rolls 24, 24. Here, the insulating resin layer is impregnated in the textile fabric 21a.

A clearance between the laminate rolls 24, 24 can be set such that substantially no pressure or a given pressure is applied when bonding the carriers with an insulating resin layer and the textile fabric.

A bonded product 22a after the bonding may be carried as such to the next step, or may be heated and pressed by the laminate rolls (25, 25), (26, 26), and (27, 27), to adjust the degree of bonding between the carriers with an insulating resin layer and the textile fabric.

In FIG. 5(2), the laminate rolls 17, 17 also act as seal rolls which prevent the air from entering the inside of the vacuum laminator 20 from the outside, for maintaining the inside of the vacuum laminator 20 under given vacuum conditions.

The bonded product 22b after the bonding is conveyed between transverse-conveying hot air ovens 28, 28, while being heated at a temperature equal to or higher than the melting temperature of the insulating resin. Thus, unfilled parts remaining in the inside of the bonded product can be eliminated.

A prepreg with a carrier 22c after heating, can be continuously winded up while being pinched by pinch rolls 29, 29, to be a roll type prepreg with a carrier 30.

Next, there will be described a prepreg with a carrier of the present invention.

A prepreg with a carrier of the present invention is characterized in that it is prepared by the process for manufacturing a prepreg with a carrier of the present invention.

There will be described a process for manufacturing a multilayer-printed circuit board of the present invention.

A process for manufacturing a multilayer-printed circuit board of the present invention comprises (c) removing at least one carrier of the prepreg with a carrier of the present invention, and (d) laminating the insulating resin layer of the prepreg with a carrier in the side where a carrier has been removed and an inner-layer circuit board on which a circuit has been formed, and then shaping the laminate.

First, there will be described the step (c).

The step (c) is removing the carrier in the prepreg with a carrier in the side to be laminated with at least the circuit-forming surface of the inner-layer circuit board to expose the insulating resin surface.

There will be described the step (d).

The step (d) is laminating the insulating resin layer in the side where a carrier of the prepreg with a carrier has been removed and an inner-layer circuit board on which a circuit has been formed, and then shaping the laminate by heating.

There are no particular restrictions to a procedure for conducting the steps (c) and (d); for example, both inner-layer circuit board and prepreg with a carrier are continuously fed while removing a carrier in the prepreg with a carrier in the inner-layer circuit board side, and the prepreg with a carrier and the inner-layer circuit board are continuously shaped using, for example, a vacuum laminator, and then they are cured by heating by a hot air oven.

There are no particular restrictions to the shaping conditions, but as an example, the shaping may be conducted at a temperature of 60 to 160° C. and a pressure of 0.2 to 3 MPa. There are no particular restrictions to the heating and curing conditions, but as an example, the heating may be conducted at a temperature of 140 to 240° C. and a duration of 30 to 120 min.

In the process for manufacturing a multilayer-printed circuit board of the present invention, it is preferable that the step (d) is conducted while the prepreg with a carrier has a carrier in the opposite side to the side where the carrier has been removed.

Thus, the insulating resin layer in the side in contact with the carrier can maintain flatness substantially comparable to the carrier surface, so that during curing the insulating resin, irregularity in the insulating resin layer along irregularity in the textile fabric surface can be prevented, to provide a multilayer-printed circuit board having an insulating resin layer excellent surface flatness.

For the multilayer-printed circuit board thus prepared, the carrier on the insulating resin layer surface is peeled off and the insulating resin layer surface can be processed to be crude by an oxidizing agent such as a permanganate and a bichromate, and then subjected to metal plating, to form a new conducting circuit.

When as a carrier, a metal foil with the side having the insulating resin layer being unprocessed to be peelable or a metal foil processed to be made more adhesive to the insulating resin layer is used, the metal foil can be etched to form a given conductor circuit.

The inner-layer circuit board used when preparing the multilayer-printed circuit board may be suitably a board prepared by, for example, forming a given conductor circuit on both sides of a copper-clad laminate by etching and blackening the conductor circuit area.

The present invention further provides a process for manufacturing a thin double-sided plate and a thin double-sided plate. There will be detailed a process for manufacturing a thin double-sided plate of the present invention and a thin double-sided plate prepared by the process.

A process for manufacturing a thin double-sided plate according to the present invention contains providing a thin double-sided plate comprising an insulating resin layer containing a backbone material of a textile fabric, wherein the insulating resin layer containing the backbone material of the textile fabric is prepared by impregnating both sides of the backbone material of the textile fabric with a first and a second insulating resin layers, and the first and the second insulating resin layers are an insulating resin layer with a carrier where the carrier is contained on the opposite side to the side to be impregnated in the backbone material of the textile fabric, and the insulating resin layer containing the backbone material of the textile fabric has a thickness of 50 μm or less.

The related art has employed a procedure that after preparing a prepreg, a carrier such as a copper foil is applied to it. However, such a procedure cannot provide a thin substrate, and encounters a problem that when applying and impregnating a resin to a textile fabric, it cannot be adequately impregnated. In contrast, the above process can provide a very thin double-sided plate where an insulating resin layer including a backbone material of the textile fabric has a thickness of 50 μm or less. The term “thin double-sided plate” as used herein, refers to that is obtained by curing an insulating resin layer including the backbone material of the textile fabric by heating.

The process for manufacturing a thin double-sided plate contains, for example,

(a) laminating the insulating resin layer sides of the first and the second insulating resin layers with a carrier and both sides of the backbone material of the textile fabric to form a laminate, and then bonding under a reduced pressure, and

(b) curing, after the bonding, the insulating resin layer comprising the backbone material of the textile fabric by heating to provide a thin double-sided plate.

A thickness of the insulating resin layer containing the backbone material of the textile fabric formed by the process of the present invention can be appropriately set, depending on, for example, a thickness of the textile fabric used, preferably 50 μm or less, more preferably equal to or more than 12 μm and equal to or less than 50 μm, further preferably equal to or more than 20 μm and equal to or less than 40 μm. The above process allows for preparing such a thin double-sided plate.

A thickness of the textile fabric which is impregnated with a resin is preferably 48 μm or less, more preferably equal to or more than 10 μm and equal to or less than 48 μm, further preferably equal to or more than 15 μm and equal to or less than 35 μm.

The textile fabric used may be, but not limited to, any of those as described above. Preferably, it is a glass fabric. The textile fabric used here is a textile fabric without an impregnated resin.

The resin material used for the insulating resin layer may be, but not limited to, any of those as described above. Preferably, the insulating resin layer consists of a resin composition containing a thermosetting resin such as a cyanate resin and/or its prepolymer, an epoxy resin, a phenol resin and a phenoxy resin.

The resin composition may further contain an inorganic filler, by which even for a thin double-sided plate with a smaller thickness prepared using a thin textile fabric, a cured product can have excellent mechanical strength and further improved low-thermal expansion.

The inorganic filler may be as described above, and among these, silica is preferable. In addition, fused silica is preferable because of its improved low-thermal expansion.

A shape of fused silica may be, for example, crushed or spherical, and in particular, spherical fused silica can be used to reduce a melt viscosity of a resin composition, so that its impregnation properties into a textile fabric base material can be improved.

A content of the inorganic filler may be, for example, 30 to 80% by weight, preferably 40 to 70% by weight to the total amount of the resin composition. It can improve the above effects of adding the inorganic filler, particular low-thermal expansion. Furthermore, since a cured product can be less water-absorptive, solder heat resistance after humidification can be improved.

Otherwise, the inorganic filler is as described above.

When the inorganic filler is contained, it is preferable to add a coupling agent. The coupling agent may be as described above.

The resin composition may contain a curing accelerator, which is as described above. Furthermore, as described above, the resin composition may further contain a thermoplastic resin such as polyimide resins, polyamide-imide resins, polyphenylene oxide resins and polyether sulfone resins. It may, if necessary, further contain additives other than those described above such as pigments and antioxidants.

The carrier may be as described above; for example, but not limited to, a metal foil or a film sheet processed to be peelable.

A procedure for bonding under reduced pressure may be as described above. For example, bonding is preferably conducted by laminating the first and the second carriers with an insulating resin layer and the textile fabric to form a laminate, which is then bonded by pressing from both sides while being passed through at least a pair of laminate rolls. Such a method allows the textile fabric to be sufficiently impregnated with the insulating resin layer.

The insulating resin layer is preferably a film. Such a film facilitates pressing and bonding by means of the rolls.

There are no particular restrictions to heating/curing means; for example, a procedure where a laminate is treated at 130° C., 150° C. and 180° C. for 2 min, respectively, in a hot air oven and then treated at 200° C. for 30 min. Here, in the hot air oven there may be placed rolls, on which the laminate is conveyed, for longer heating/curing processing within a short hot air oven.

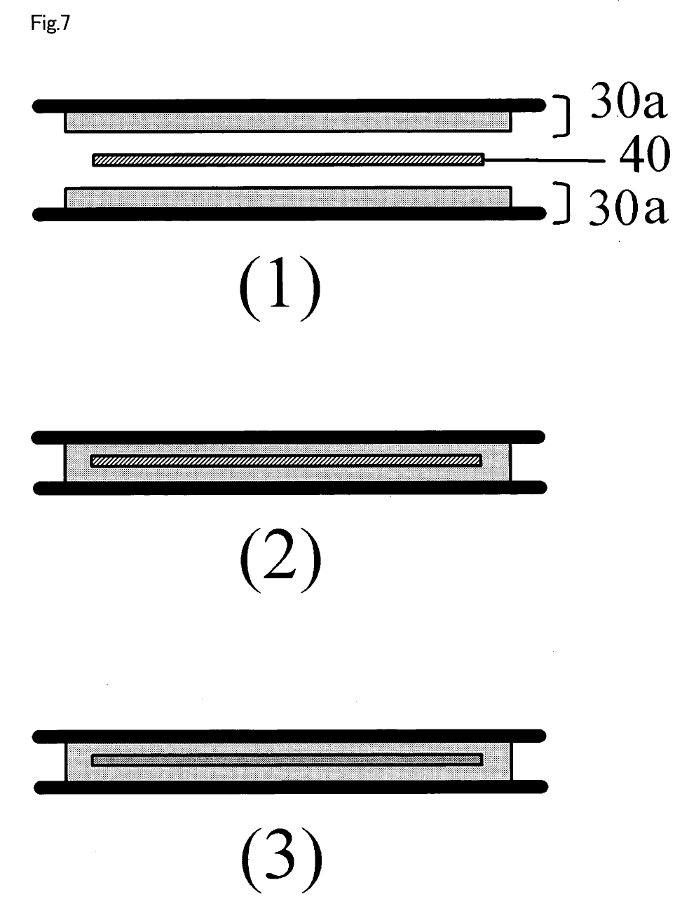

FIG. 7 is a schematic view illustrating an embodiment of a thin double-sided plate manufactured by a process of the present invention. In FIG. 2(1) to (3), the first carrier with an insulating resin layer 30a and the second carrier with an insulating resin layer 30a have a carrier having a width-directional dimension larger than that of the textile fabric 40 and have an insulating resin layer having a width-directional dimension larger than that of the textile fabric 4. Here, FIG. 7(1) shows relation in a width-directional dimension for each of a carrier, an insulating resin layer and a textile fabric.

In a process for manufacturing a thin double-sided plate of the present invention, besides the above embodiment, one of the two carriers with an insulating resin layer, for example, the first carrier with an insulating resin layer may have an insulating resin layer having a width-directional dimension larger than that of the textile fabric 4 while the second carrier with an insulating resin layer may have an insulating resin layer having a width-directional dimension equal to that of the textile fabric 4. As another embodiment, the first carrier with an insulating resin layer and the second carrier with an insulating resin layer may have an insulating resin layer having a width-directional dimension equal to that of the textile fabric 4.

Among these embodiments, it is preferable that the first carrier with an insulating resin layer and the second carrier with an insulating resin layer have a carrier having a width-directional dimension larger than that of the textile fabric and either or both of the carriers with an insulating resin layer have an insulating resin layer having a width-directional dimension larger than that of the textile fabric.

Furthermore, a thin double-sided plate can be used for manufacturing a multilayer-printed circuit board. There will be described a process for manufacturing a multilayer-printed circuit board of the present invention.

A process for manufacturing a multilayer-printed circuit board of the present invention may be, for example, as follows. A through hole for interlayer connection is formed in a thin double-sided plate of the present invention, and then a circuit is fabricated by subtractive technique. Then, a given build-up material is deposited and a process for interlayer connection and circuit fabrication is repeated by additive technique, to manufacture a multilayer-printed circuit board. Here, since the thin double-sided plate of the present invention can be continuously prepared, the multilayer-printed circuit board can also be continuously manufactured.

As described above, according to the manufacturing process of the present invention, there is provided a process for continuously manufacturing a prepreg with carriers having an insulating resin layer containing a backbone material of a textile fabric, by which a prepreg with carriers exhibiting excellent impregnating properties and thickness precision can be conveniently manufactured. In particular, even when using a thin textile fabric, an internal strain can be reduced to achieve excellent impregnating properties.

Furthermore, a multilayer-printed circuit board prepared using a prepreg with carriers of the present invention exhibits excellent mechanical properties such as warpage and dimension stability as well as moldability, and can be suitably used for an application such as a printed circuit board required to be high density and highly layered, which must be highly reliable. Furthermore, a prepreg with carriers prepared using a cyanate resin further exhibits improved heat resistance and low-thermal expansion, and can be suitably used in an application requiring higher reliability such as a printed circuit board which is needed to be thinner.

Furthermore, according to the manufacturing process of the present invention, there is provided a process for continuously manufacturing a thin double-sided plate having an insulating resin layer containing a backbone material of a textile fabric, by which a thin double-sided plate exhibiting excellent impregnating properties and thickness precision can be conveniently manufactured. In particular, even when using a thin textile fabric, an internal strain can be reduced to achieve excellent impregnating properties.

### EXAMPLES

There will be described the present invention with reference to, but not limited to, experimental examples.

### A-1. Preparation of a Liquid Resin Compositional for Forming an Insulating Resin Layer

In 100 parts by weight of methyl cellosolve were dissolved 100 parts by weight of an epoxy resin (Japan Epoxy Resins Co., Ltd.; “Ep5048”), 2 parts by weight of a curing agent (dicyandiamide) and 0.1 parts by weight of a curing accelerator (2-ethyl-4-methyl imidazole) as resin components, to prepare a resin varnish.

A-2. Preparation of a Carrier with an Insulating Resin Layer
(1) Preparation of a Carrier with an Insulating Resin Layer A1

A polyethylene terephthalate film with a thickness of 35 μm and a width of 480 mm was used as a carrier.

Using an apparatus shown in FIG. 5(1), on the carrier was applied the liquid resin compositional prepared above by a comma coater, and then dried in an oven at 170° C. for 3 min, to form a film consisting of an insulating resin layer with a thickness of 20 μm and a width of 410 mm, such that it was placed at the center of the carrier in the width direction.

On this insulating resin layer side was laminated a protecting film (polyethylene), to prepare a carrier with an insulating resin layer.

(2) Preparation of a Carrier with an Insulating Resin Layer A2

As a carrier the same carrier as in the carrier with an insulating resin layer A1 above was employed.

Using an apparatus shown in FIG. 5(1), on the carrier was applied the liquid resin compositional prepared above by a comma coater, and then dried in an oven at 170° C. for 3 min, to form a film consisting of an insulating resin layer with a thickness of 20 μm and a width of 360 mm, such that it was placed at the center of the carrier in the width direction.

On this insulating resin layer side was laminated a protecting film (polyethylene), to prepare a carrier with an insulating resin layer.

A-3. Preparation of a Prepreg with a Carrier

### Experimental Example A1

A glass fabric (Unitica Glass Fiber Co., Ltd.; “E02Z-SK”, width: 360 mm, grammage: 17 g/m²) was used as a textile fabric.

Two carriers with an insulating resin layer A1 prepared above were used as a first and a second carriers with an insulating resin layer.

Using the apparatus as shown in FIG. 5(2), while the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls (24) at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric, and in the outer region of the textile fabric in the width-directional dimension, the insulating resin layers of the first and the second carriers with an insulating resin layer were bonded to each other.

Then, the above bonded product was heated by passing it through a transverse-conveying hot air oven maintained at 120° C. over 2 min for melting the insulating resin layers without applying any pressure, to prepare a prepreg with carriers.

### Experimental Example A2

As a textile fabric the same textile fabric as in Experimental Example A1 was employed.

The carrier with an insulating resin layer A1 prepared above was used as a first carrier with an insulating resin layer and the carrier with an insulating resin layer A2 was used as a second carrier with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls (24) at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric, and in the outer region of the textile fabric in the width-directional dimension, the insulating resin layer of the first carrier with an insulating resin layer and the carrier of the second carrier with an insulating resin layer were bonded.

Then, the above bonded product was heated by passing it through a transverse-conveying hot air oven maintained at 120° C. over 2 min for melting the insulating resin layers without applying any pressure, to prepare a prepreg with a carrier.

### Experimental Example A3

As a textile fabric the same textile fabric as in Experimental Example A1 was employed.

Two carriers with an insulating resin layer A2 (two) prepared above were used as a first and a second carriers with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls (24) at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric.

Then, the above bonded product was heated by passing it through a transverse-conveying hot air oven maintained at 120° C. over 2 min for melting the insulating resin layers without applying any pressure, to prepare a prepreg with a carrier.

### Experimental Example A4

A prepreg with carriers was prepared as described in Experimental Example A1, except that the first and the second carriers with an insulating resin layer and the textile fabric were bonded under a pressure reduced by 730 Torr.

### Experimental Example A5

As a textile fabric the same textile fabric as in Experimental Example A1 was employed.

Two carriers with an insulating resin layer A1 (two) prepared above were used as a first and a second carriers with an insulating resin layer.

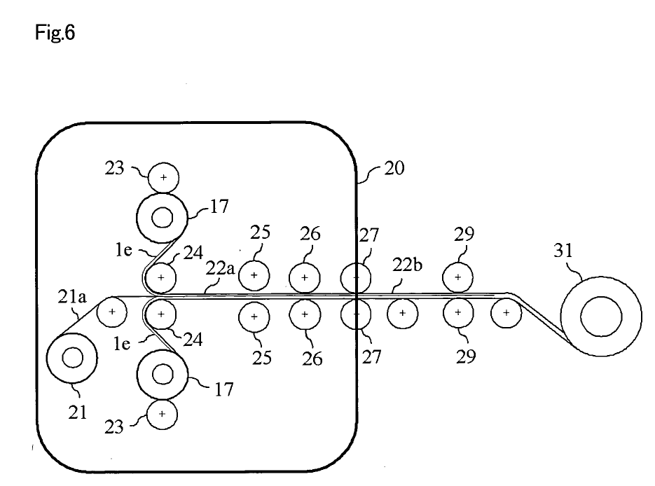

The apparatus as shown in FIG. 6 (in the figure, the common components with the configuration of FIG. 5(2) were denoted by the same symbols used in FIG. 5(2)) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls (24) at 80° C. under an ambient pressure, to prepare a prepreg with carriers 31.

### Experimental Example A6

As a textile fabric the same textile fabric as in Experimental Example A1 was employed.

Two carriers with an insulating resin layer A1 (two) prepared above were used as a first and a second carriers with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls (24) at 80° C. under an ambient pressure.

Then, the above bonded product was heated by passing it through a transverse-conveying hot air oven maintained at 120° C. over 2 min for melting the insulating resin layers without applying any pressure, to prepare a prepreg with a carrier.

### A-4. Preparation of a Multilayer-Printed Circuit Board

A printed circuit board on which a circuit was formed with an insulating layer thickness: 0.6 mm, a circuit thickness: 12 μm and a circuit line width and an inter-circuit space: L/S=50/50 was used as an inner-layer circuit board.

From one side of the prepreg with carriers prepared in Experimental Examples, the carrier was peeled off to expose the insulating resin layer, while the carrier in the other side was left untouched. Each side of the inner-layer circuit board was laminated with the insulating resin layer of the prepreg with a carrier, and the laminate was shaped at a temperature of 120° C. and a pressure of 1.5 MPa under a pressure reduced by 750 Torr. Then, it was heated in an oven at 200° C., to prepare a multilayer-printed circuit board.

### A-5. Evaluation

The prepreg with a carrier and the multilayer-printed circuit board prepared in the above Experimental Examples were evaluated for their properties. The results are shown in Table 1.

TABLE 1

| | | Thickness | |
|---|---|---|---|
| | | precision | |
| | | Aver- | Devia- |
| | Impregnation properties | age | tion |
| Exp. Example A1 | No permeation of a penetrant | 45 μm | 0.6 μm |
| | from the end to the center | | |
| | and no swelling | | |
| Exp. Example A2 | No permeation of a penetrant | 45 μm | 0.6 μm |
| | from the end to the center | | |
| | and no swelling | | |
| Exp. Example A3 | Slight permeation of a | 45 μm | 0.6 μm |
| | penetrant in the end and | | |
| | swelling | | |
| Exp. Example A4 | No permeation of a penetrant | 45 μm | 0.6 μm |
| | from the end to the center | | |
| | and no swelling | | |
| Exp. Example A5 | Permeation of a penetrant | 51 μm | 4.6 μm |
| | from the end to the center | | |
| | and swelling | | |
| Exp. Example A6 | Permeation of a penetrant | Unmea- | Unmeas- |
| | from the end to the center | surable | urable |
| | and swelling | | |

Evaluation methods are as follows.

### (1) Impregnation Properties

A cross section of prepregs with a carrier prepared in Experimental Examples was immersed in a fluorescent penetrant, and the presence of permeation by the fluorescent penetrant was observed by a microscope.

In addition, a prepreg with a carrier was treated with PCT

(121° C./100%/120 min), and then immersed in a solder bath at 260° C. for 30 sec. Then presence of swelling was observed.

### (2) Thickness Precision

A cross section of prepregs with a carrier prepared in Experimental Examples was observed by a microscope to determine a thickness at three points at a pitch of 120 mm in a width direction, from which an average and a standard deviation were calculated.

Experimental Examples A1 to A4 are related to a prepreg with a carrier of the present invention, which exhibits excellent impregnation properties and thickness precision. Particularly, in Experimental Examples A1, A2 and A4, the first and the second carriers with an insulating resin layer has a carrier having a width-directional dimension larger than that of the textile fabric, and either or both has an insulating resin layer having a width-directional dimension larger than that of the textile fabric, resulting in particularly excellent impregnation properties.

Experimental Example A5 gave a bonded product of carriers with an insulating resin layer and a textile fabric under an ambient pressure, which exhibited insufficient impregnation properties.

Experimental Example A5 gave a bonded product of carriers with an insulating resin layer and a textile fabric at an ambient pressure, which was then heated. However, since swelling was occurred during the heating, thickness precision could not be determined and a prepreg with a carrier could not be prepared.

### B-1. Materials for a Liquid Resin Composition

The materials used for a liquid resin composition are as follows.

(1) Cyanate resin 1: novolac type cyanate resin (Lonza Japan Ltd., “PRIMASET PT-30”, Mw: about 700)

(2) Cyanate resin 2: novolac type cyanate resin (Lonza Japan Ltd., “PRIMASET PT-60”, Mw: about 2,600)

(3) Cyanate resin 3: bisphenol-A type cyanate resin (Asahi Kasei Epoxy Co., Ltd., “AroCyB-30”)

(4) Epoxy resin: biphenyldimethylene type epoxy resin (Nippon Kayaku Co., Ltd., “NC-3000”, epoxy equivalent: 275)

(5) Phenol resin: biphenyldimethylene type phenol resin (Nippon Kayaku Co., Ltd., “GPH-103”, hydroxy equivalent: 203)

(6) Phenoxy resin 1/a copolymer of a biphenylepoxy resin and a bisphenol-S epoxy resin having terminal epoxy groups: Japan Epoxy Resins Co., Ltd. “YX-8100H30”, weight average molecular weight: 30,000)

(7) Phenoxy resin 2/a copolymer of a bisphenol-A type epoxy resin and a bisphenol-F type epoxy resin having terminal epoxy groups: Japan Epoxy Resins Co., Ltd. “Epikote 4275”, weight average molecular weight: 60,000)

(8) Curing accelerator/an imidazole compound: Shikoku Chemicals Corporation, “1-benzyl-2-phenylimidazole”

(9) Inorganic filler 1: spherical fused silica (DENKI KAGAKU KOGYO KABUSHIKI KAISHA, “SFP-10X”, average particle size: 0.3 μm)

(10) Inorganic filler 2: spherical fused silica (ADMATECHS CO., LTD., “SO-32R”, average particle size: 1.5 μm)

(11) Inorganic filler 3: spherical fused silica (ADMATECHS CO., LTD., “SO-25R”, average particle size: 0.5 μm)

(12) Coupling agent: epoxy silane type coupling agent (Nippon Unicar Co., Ltd., “A-187”).

### B-2. Preparation of a Liquid Resin Composition for Preparation of an Insulating Resin Layer Containing a Cyanate Resin

Contents of the components are on the basis of solid.

### 2.1 Preparation of Liquid Resin Composition b1 for Forming an Insulating Resin Layer

In methyl ethyl ketone at an ambient temperature were dissolved 15 parts by weight of cyanate resin 1, 5 parts by weight of cyanate resin 2, 10 parts by weight of an epoxy resin, 10 parts by weight of a phenol resin.

Then, to the mixture were added 10 parts by weight of inorganic filler 1, 50 parts by weight of inorganic filler 2 and 0.5 parts by weight of a coupling agent to the total 100 parts by weight of inorganic filler 1 and inorganic filler 2, and the mixture was mixed under stirring by a high-speed stirrer for 10 min, to prepare liquid resin composition b1.

### 2.2 Preparation of Liquid Resin Composition b2 for Forming an Insulating Resin Layer

In methyl ethyl ketone at an ambient temperature were dissolved 25 parts by weight of cyanate resin 1, 25 parts by weight of an epoxy resin, 10 parts by weight of phenoxy resin 1 and 0.4 parts by weight of a curing accelerator.

Then, to the mixture were added 40 parts by weight of inorganic filler 3 and 0.5 parts by weight of a coupling agent to the total 100 parts by weight of inorganic filler 3, and the mixture was mixed under stirring by a high-speed stirrer for 10 min, to prepare liquid resin composition b2.

### 2.3 Preparation of Liquid Resin Composition b3 for Forming an Insulating Resin Layer

In methyl ethyl ketone at an ambient temperature were dissolved 25 parts by weight of cyanate resin 1, 25 parts by weight of an epoxy resin, 5 parts by weight of phenoxy resin 1, 5 parts by weight of phenoxy resin 2 and 0.4 parts by weight of a curing accelerator.

Then, to the mixture were added 40 parts by weight of inorganic filler 3 and 0.5 parts by weight of a coupling agent to the total 100 parts by weight of inorganic filler 3, and the mixture was mixed under stirring by a high-speed stirrer for 10 min, to prepare liquid resin composition b3.

### 2.4 Preparation of Liquid Resin Composition b4 for Forming an Insulating Resin Layer

In methyl ethyl ketone at an ambient temperature were dissolved 20 parts by weight of cyanate resin 3, 12 parts by weight of an epoxy resin and 8 parts by weight of a phenol resin.

Then, to the mixture were added 10 parts by weight of inorganic filler 1, 50 parts by weight of inorganic filler 2 and 0.5 parts by weight of a coupling agent to the total 100 parts by weight of inorganic filler 1 and inorganic filler 2, and the mixture was mixed under stirring by a high-speed stirrer for 10 min, to prepare liquid resin composition b4.

### 2.5 Preparation of Liquid Resin Composition b5 for Forming an Insulating Resin Layer

In 100 parts by weight of methyl cellosolve were dissolved 100 parts by weight of an epoxy resin (Japan Epoxy Resins Co., Ltd. “Ep5048”), 2 parts by weight of a curing agent (dicyandiamide) and 0.1 parts by weight of a curing accelerator (2-ethyl-4-methylimidazole), to prepare liquid resin composition b5.

B-3. Preparation of a Carrier with an Insulating Resin Layer
3.1 Preparation of Carrier with an Insulating Resin Layer B-1

A carrier was a polyethylene terephthalate film (Mitsubishi Polyester Film GmbH, Diafoil) with a thickness of 35 μm and a width of 480 mm.

An apparatus shown in FIG. 5(1) was used. On the carrier was applied the liquid resin composition 1 prepared above by a comma coater, and then dried in an oven at 150° C. for 3 min, to form a film consisting of an insulating resin layer with a thickness of 20 μm and a width of 410 mm, such that it was placed at the center of the carrier in the width direction. The insulating resin layer thus obtained was a film.

On this insulating resin layer side was laminated a protecting film (polyethylene), to prepare a carrier with an insulating resin layer B-1.

3.2 Preparation of Carrier with an Insulating Resin Layer B-2

Carrier with an insulating resin layer B-2 was prepared as described in 3.1 above, substituting liquid resin composition b2 for liquid resin composition b1.

3.3 Preparation of Carrier with an Insulating Resin Layer B-3

Carrier with an insulating resin layer B-3 was prepared as described in 3.1 above, substituting liquid resin composition b3 for liquid resin composition b1.

3.4 Preparation of Carrier with an Insulating Resin Layer B-4

Carrier with an insulating resin layer B-4 was prepared as described in 3.1 above, substituting liquid resin composition b4 for liquid resin composition b1.

3.5 Preparation of Carrier with an Insulating Resin Layer C

The same carrier as in the carrier with an insulating resin layer B was employed.

An apparatus shown in FIG. 5(1) was used. On the carrier was applied the liquid resin composition 3 prepared above by a comma coater, and then dried in an oven at 150° C. for 3 min, to form an insulating resin layer with a thickness of 20 μm and a width of 360 mm, such that it was placed at the center of the carrier in the width direction. The insulating resin layer thus obtained was a film.

On this insulating resin layer side was laminated a protecting film (polyethylene), to prepare a carrier with an insulating resin layer C.

3.6 Preparation of Carrier with an Insulating Resin Layer D

The same carrier as in the carrier with an insulating resin layer B was employed.

An apparatus shown in FIG. 5(1) was used. On the carrier was applied the liquid resin composition 5 prepared above by a comma coater, and then dried in an oven at 170° C. for 3 min, to form an insulating resin layer with a thickness of 20 μm and a width of 410 mm, such that it was placed at the center of the carrier in the width direction. The insulating resin layer thus obtained was a film.

On this insulating resin layer side was laminated a protecting film (polyethylene), to prepare a carrier with an insulating resin layer D.

B-4. Preparation of a Prepreg with a Carrier

### 4.1 Experimental Example B1

A glass fabric (Unitica Glass Fiber Co., Ltd., “E02Z-SK”, width: 360 mm, grammage: 17 g/m²) was used as a textile fabric.

Two carriers with an insulating resin layer B-1 prepared above were used as a first and a second carriers with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls 24 at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric, and in the outer region of the textile fabric in the width-directional dimension, the insulating resin layers of the first and the second carriers with an insulating resin layer were bonded to each other.

Then, the above bonded product was heated by passing it through a transverse-conveying hot air oven maintained at 120° C. over 2 min without applying any pressure, to prepare a prepreg with carriers.

### 4.2 Experimental Example B2

A prepreg with carriers was prepared as described in Experimental Example B1, substituting a carrier with an insulating resin layer B-2 for a carrier with an insulating resin layer B-1.

### 4.3 Experimental Example B3

A prepreg with carriers was prepared as described in Experimental Example B1, substituting a carrier with an insulating resin layer B-3 for a carrier with an insulating resin layer B-1.

### 4.4 Experimental Example B4

A prepreg with carriers was prepared as described in Experimental Example B1, substituting a carrier with an insulating resin layer B-4 for a carrier with an insulating resin layer B-1.

### 4.5 Experimental Example B5

The same textile fabric as in Experimental Example B1 was used.

“Carrier with an insulating resin layer B-3” and “carrier with an insulating resin layer C” prepared above were used as a first and a second carriers with an insulating resin layer, respectively.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls 24 at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric, and in the outer region of the textile fabric in the width-directional dimension, the insulating resin layer of the first carrier with an insulating resin layer was bonded to the carrier of the second carrier with an insulating resin layer.

Then, the above bonded product was heated by passing it through a transverse-conveying hot air oven set at 120° C. for 2 min without applying any pressure, to prepare a prepreg with carriers.

### 4.6 Experimental Example B6

The same textile fabric as in Experimental Example B1 was used. Two of “Carriers with an insulating resin layer C” prepared above were used as a first and a second carriers with an insulating resin layer. The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls 24 at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric.

Then, the above bonded product was heated by passing it through a transverse-conveying hot air oven set at 120° C. for 2 min without applying any pressure, to prepare a prepreg with carriers.

### 4.7 Experimental Example B7

A prepreg with a carrier was prepared as described in Experimental Example B1, except that the first and the second carriers with an insulating resin layer were bonded to the textile fabric under a pressure reduced by 740 Torr.

### 4.8 Experimental Example B8

The same textile fabric as in Experimental Example B1 was used.

Two carriers with an insulating resin layer D prepared above were used as a first and a second carriers with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls 24 at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric, and in the outer region of the textile fabric in the width-directional dimension, the insulating resin layers of the first and the second carriers with an insulating resin layer were bonded to each other.

Then, the above bonded product was heated by passing it through a transverse-conveying hot air oven set at 120° C. for 2 min without applying any pressure, to prepare a prepreg with carriers.

### 4.9 Experimental Example B9

The same textile fabric as in Experimental Example B1 was used.

Two carriers with an insulating resin layer B-1 prepared above were used as a first and a second carriers with an insulating resin layer.

The apparatus as shown in FIG. 6 was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls (24) at 80° C. under an ambient pressure, to prepare a prepreg with carriers 31.

### 4.10 Experimental Example B10

The same textile fabric as in Experimental Example B1 was used.

Two Carriers with an insulating resin layer B-1 prepared above were used as a first and a second carriers with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction. They were bonded using laminate rolls 24 at 80° C. under an ambient pressure.

Then, the above bonded product was heated by passing it through a transverse-conveying hot air oven set at 120° C. for 2 min without applying any pressure, to prepare a prepreg with carriers.

### B-5. Preparation of a Multilayer-Printed Circuit Board

A printed circuit board on which a circuit was formed with an insulating layer thickness: 0.6 mm, a circuit thickness: 12 μm and a circuit line width and an inter-circuit space: L/S=50 μm/50 μm was used as an inner-layer circuit board.

From one side of the prepreg with carriers prepared in Experimental Examples, the carrier was peeled off to expose the insulating resin layer, while the carrier in the other side was left untouched.

Each side of the inner-layer circuit board was laminated with the insulating resin layer of the prepreg with a carrier, and the laminate was shaped, using “Becquerel Laminator MVLP” from Meiki Co., Ltd., at 80° C. under a pressure reduced by 750 Torr from an ambient pressure, at 0.5 MPa for 30 sec, and then at 120° C. and 1.5 MPa for 60 sec. Then, it was heated in an oven at 200° C. for 1 hour, to prepare a multilayer-printed circuit board for evaluation.

### B-6. Evaluation

The prepreg with a carrier and the multilayer-printed circuit board prepared in the above Experimental Examples were evaluated for their properties. The results are shown in Table 2.

TABLE 2

| | | | | Thermal | |
|---|---|---|---|---|---|
| | | Thickness precision | | expansion | Heat |
| | Impregnation | (μm) | | coefficient | resistance |
| | properties | Average | Deviation | (ppm) | (-) |
| Exp. | No permeation of a | 45 | 0.6 | 11 | None |
| Example B1 | penetrant from the | | | | |
| | end to the center and | | | | |
| | no swelling | | | | |
| Exp. | No permeation of a | 43 | 0.5 | 16 | None |
| Example B2 | penetrant from the | | | | |
| | end to the center and | | | | |
| | no swelling | | | | |
| Exp. | No permeation of a | 44 | 0.5 | 17 | None |
| Example B3 | penetrant from the | | | | |
| | end to the center and | | | | |
| | no swelling | | | | |
| Exp. | No permeation of a | 47 | 0.8 | 13 | None |
| Example B4 | penetrant from the | | | | |
| | end to the center and | | | | |
| | no swelling | | | | |
| Exp. | No permeation of a | 43 | 0.5 | 17 | None |
| Example B5 | penetrant from the | | | | |
| | end to the center and | | | | |
| | no swelling | | | | |
| Exp. | Slight permeation of | 46 | 0.7 | 16 | None |
| Example B6 | a penetrant in the end | | | | |
| | and swelling | | | | |
| Exp. | No permeation of a | 45 | 0.6 | 11 | None |
| Example B7 | penetrant from the | | | | |
| | end to the center and | | | | |
| | no swelling | | | | |
| Exp. | No permeation of a | 45 | 0.6 | 16 | None |
| Example B8 | penetrant from the | | | | |
| | end to the center and | | | | |
| | no swelling | | | | |
| Exp. | Permeation of a | 50 | 4.5 | Unmeasurable | Swelling |
| Example B9 | penetrant from the | | | | |
| | end to the center and | | | | |
| | swelling | | | | |
| Exp. | Permeation of a | Unmeasurable | Unmeasurable | — | — |
| Example B10 | penetrant from the | | | | |
| | end to the center and | | | | |
| | swelling | | | | |

Evaluation methods are as follows.

### (1) Impregnation Properties

A cross section of prepregs with a carrier prepared in Experimental Examples was immersed in a fluorescent penetrant, and the presence of permeation by the fluorescent penetrant was observed by a microscope.

In addition, a prepreg with a carrier was treated with PCT

(121° C./100%/120 min), and then immersed in a solder bath at 260° C. for 30 sec. Then presence of swelling was observed.

### (2) Thickness Precision

A cross section of prepregs with a carrier prepared in Experimental Examples was observed by a microscope to determine a thickness at three points at a pitch of 120 mm in a width direction, from which an average and a standard deviation were calculated.

### (3) Thermal Expansion Coefficient in a Plane Direction of a Prepreg

A thermal expansion coefficient in a plane direction for the prepregs with a carrier prepared in Experimental Examples was determined at a temperature increase rate of 10° C./min using a TMA apparatus (TA Instruments).

(4) Solder Heat Resistance after Humidification

A 50 mm×50 mm test piece was cut out from multilayer-printed circuit boards prepared using prepregs with a carrier obtained in Experimental Examples, PCT-treated (121° C./100%/120 min), and then immersed in a solder bath at 260° C. for 30 sec. It was observed for the presence of swelling. It was rated “None” when swelling was not observed and “Swelling” when swelling was observed.

Experimental Examples B1 to B7 relate to a prepreg with a carrier of the present invention, which exhibited excellent impregnation properties and thickness precision. Particularly, in Experimental Examples B1 to B5, the first and the second carriers with an insulating resin layer has a carrier having a width-directional dimension larger than that of the textile fabric, and either or both has an insulating resin layer having a width-directional dimension larger than that of the textile fabric and furthermore shaping was conducted under a pressure reduced by 740 Torr or more from an ambient pressure, resulting in particularly excellent impregnation properties.

Experimental Examples B1 to B7 used a resin composition containing a cyanate resin, so that thermal expansion of a prepreg could be lowered and heat resistance of a multilayer-printed circuit board could be improved by the synergy with good impregnation properties.

Experimental Example B8 used a resin composition free from a cyanate resin, and was excellent in impregnation properties and thickness precision of a prepreg with a carrier.

Experimental Example B9 gave a bonded product of carriers with an insulating resin layer using a resin composition containing a cyanate resin and a textile fabric under an ambient pressure, which exhibited insufficient impregnation properties.

Experimental Example B10 gave a bonded product of carriers with an insulating resin layer prepared using a resin composition containing a cyanate resin and a textile fabric at an ambient pressure, which was then heated. However, since swelling was occurred during the heating, thickness precision could not be determined and a prepreg with a carrier could not be prepared.

### C-1. Materials for a Liquid Resin Composition

The materials for the liquid resin composition in this Experimental Example were as described for B-1.

### C-2. Preparation of a Liquid Resin Composition c1 for Forming an Insulating Resin Layer

In methyl ethyl ketone at an ambient temperature were dissolved 25 parts by weight of cyanate resin 1, 25 parts by weight of an epoxy resin, 10 parts by weight of phenoxy resin 1 and 0.4 parts by weight of a curing accelerator. Then, to the mixture were added 40 parts by weight of inorganic filler 3 and 0.5 parts by weight of a coupling agent to the total 100 parts by weight of inorganic filler 3, and the mixture was mixed under stirring by a high-speed stirrer for 10 min, to prepare a liquid resin composition.

C-3. Preparation of a Carrier with an Insulating Resin Layer

### 3.1 Preparation of Copper Foil Having an Insulating Resin Layer 1

A copper foil (Nippon Denkai Ltd., F2WS-12) with a thickness 12 μm and a width of 480 mm was used as a carrier. An apparatus shown in FIG. 5(1) was used. On the carrier was applied the liquid resin composition c1 prepared above by a comma coater, and then dried in an oven at 150° C. for 3 min, to form an insulating resin layer with a thickness of 14 μm and a width of 410 mm, such that it was placed at the center of the carrier in the width direction. The insulating resin layer thus obtained was in a form of a film.

On this insulating resin layer side was laminated a protecting film (polyethylene), to prepare a copper foil with an insulating resin layer 1.

### 3.2 Preparation of a Copper Foil Having an Insulating Resin Layer 2

A copper foil having an insulating resin layer 2 was prepared as described in 3.1 above, except that a thickness of the insulating resin layer was 11.5 μm.

### 3.3 Preparation of a Copper Foil Having an Insulating Resin Layer 3

A copper foil having an insulating resin layer 3 was prepared as described in 3.1 above, except that a thickness of the insulating resin layer was 9 μm.

### 3.4 Preparation of a Copper Foil Having an Insulating Resin Layer 4

A copper foil having an insulating resin layer 4 was prepared as described in 3.1 above, except that a thickness of the insulating resin layer was 7 μm.

### C-4. Preparation of a Thin Double-Sided Plate

### 4.1 Experimental Example C1

A glass fabric (Unitica Glass Fiber Co., Ltd., “E02Z-SK”, width: 360 mm, grammage: 17 g/m²) was used as a textile fabric.

Two copper foils with an insulating resin 1 prepared above were used as a first and a second carriers with an insulating resin layer.

The apparatus as shown in FIG. 5(2) was used. While the protecting films of the first and the second carriers with an insulating resin layer were peeled, the insulating resin layer sides of the carriers with an insulating resin layer were laminated on both sides of the textile fabric, such that the textile fabric was placed at the center of the carrier in the width direction, to prepare a laminate. The laminate was bonded by pressing it from both sides using laminate rolls 24 at 80° C. under a pressure reduced by 750 Torr.

Here, in the inner region of the textile fabric in the width-directional dimension, the insulating resin layer sides of the first and the second carriers with an insulating resin layer were bonded to both sides of the textile fabric, and in the outer region of the textile fabric in the width-directional dimension, the insulating resin layers of the first and the second carriers with an insulating resin layer were bonded to each other.

Then, the above bonded product was passed through transverse-conveying hot air ovens maintained at 130° C., 150° C. and 180° C. for 2 min at each temperature. Then, it was passed through an oven at 200° C. over 30 min for heating and curing it without applying any pressure, to prepare a double-sided copper-clad plate.

### 4.2 Experimental Example C2

A double-sided copper-clad plate was prepared as described in Example C1, substituting a copper foil with an insulating resin layer 2 for a copper foil with an insulating resin layer 1.

### 4.3 Experimental Example C3

A double-sided copper-clad plate was prepared as described in Example C1, substituting a copper foil with an insulating resin layer 3 for a copper foil with an insulating resin layer 1.

### 4.4 Experimental Example C4

A double-sided copper-clad plate was prepared as described in Example C1, substituting a copper foil with an insulating resin layer 4 for a copper foil with an insulating resin layer 1.

### 5. Evaluation

The double-sided copper-clad plates prepared in the above examples were evaluated for their thickness. Here, a plate thickness is the sum of a thickness of an insulating resin layer containing a backbone material of a textile fabric and a thickness of a copper foil. The results are shown in Table 1.

TABLE 3

| | Plate | Thickness of an insulating resin layer |
|---|---|---|
| | thickness | containing a backbone material of a |
| | [μm] | textile fabric [μm] |
| Exp. Example C1 | 59 | 35 |
| Exp. Example C2 | 54 | 30 |
| Exp. Example C3 | 49 | 25 |
| Exp. Example C4 | 44 | 20 |

The double-sided copper-clad plates prepared in Experimental Examples C1 to C4 are thin double-sided plates of the present invention, exhibiting excellent thickness precision in an insulating resin layer containing a textile fabric. Since shaping was conducted under a pressure reduced by 740 Torr from an ambient pressure, impregnation properties were particularly improved. After heating and curing, sufficiently thin double-sided plates were obtained.

1. A process for continuously manufacturing a prepreg with carriers comprising an insulating resin layer having a backbone material of a textile fabric,
(a) laminating each insulating resin layer side of a first and a second carriers comprising an insulating resin layer on one side on the both sides of the textile fabric, respectively, to form a laminate and bonding them under a reduced pressure, and
(b) after said bonding, heating the laminate at a temperature equal to or higher than a melting point of said insulating resin.

2. The process as claimed in claim 1, wherein in said step (a), said laminate is bonded by pressing it from both sides with at least a pair of laminate rolls.

3. The process as claimed in claim 2, wherein said insulating resin layer in said laminate is a film.

4. The process for manufacturing a prepreg with carriers as claimed in claim 1, wherein
said first and said second carriers with an insulating resin layer comprise a carrier having a larger dimension than that of said textile fabric in a width direction, and
said first and said second carriers with an insulating resin layer comprise an insulating resin layer having a larger dimension than that of said textile fabric in a width direction.

5. The process for manufacturing a prepreg with carriers as claimed in claim 4, wherein in said step (a),
in the inner region of the dimension in a width direction of said textile fabric, the insulating resin layer sides of said first and said second carriers with an insulating resin layer are bonded to the both sides of said textile fabric, respectively, and
in the outer region of the dimension in a width direction of said textile fabric, the insulating resin layers of said first and said second carriers with an insulating resin layer are bonded each other.

6. The process for manufacturing a prepreg with carriers as claimed in claim 1, wherein
said first and second carriers with an insulating resin layer comprise a carrier having a larger dimension than that of said textile fabric in a width direction, and
said first carrier with an insulating resin layer comprises an insulating resin layer having a larger dimension than that of said textile fabric in a width direction.

7. The process for manufacturing a prepreg with carriers as claimed in claim 6, wherein in said step (a),
in the inner region of the dimension in a width direction of said textile fabric, the insulating resin layer sides of said first and second carriers with an insulating resin layer are bonded to the both sides of said textile fabric, respectively, and
in the outer region of the dimension in a width direction of said textile fabric, the insulating resin layer of said first carrier with an insulating resin layer and the carrier of said second carrier with an insulating resin layer are bonded.

8. The process for manufacturing a prepreg with carriers as claimed in claim 1, wherein said step (a) is conducted using a vacuum laminator.

9. The process for manufacturing a prepreg with carriers as claimed in claim 1, wherein said step (b) is conducted substantially without applying any pressure to the bonded product formed in said step (a).

10. The process for manufacturing a prepreg with carriers as claimed in claim 1, wherein said textile fabric is a glass fabric.

11. The process for manufacturing a prepreg with carriers as claimed in claim 1, wherein said first and/or said second carriers with an insulating resin layer comprise a film sheet whose surface on which said insulating resin layer is to be formed is processed to be peelable.

12. The process for manufacturing a prepreg with carriers as claimed in claim 1, wherein said first and/or said second carriers with an insulating resin layer comprise a metal foil.

13. The process for manufacturing a prepreg with carriers as claimed in claim 1, wherein said insulating resin layer is prepared from a resin composition containing a cyanate resin.

14. The process for manufacturing a prepreg with carriers as claimed in claim 1, wherein said resin composition is prepared from a resin composition containing an epoxy resin.

15. The process for manufacturing a prepreg with carriers as claimed in claim 1, wherein said resin composition is prepared from a resin composition containing a phenol resin.

16. The process for manufacturing a prepreg with carriers as claimed in claim 13, wherein said resin composition is prepared from a resin composition further containing a phenoxy resin.

17. The process for manufacturing a prepreg with carriers as claimed in claim 1, wherein said resin composition further comprises an inorganic filler.

18. A process for continuously manufacturing a prepreg with carriers comprising an insulating resin layer having a backbone material of a textile fabric,
(a) laminating each insulating resin layer side of a first and a second carriers comprising an insulating resin layer on one side on the both sides of said textile fabric, respectively, to form a laminate and bonding them under a reduced pressure, and
(b) after said bonding, heating the laminate at a temperature equal to or higher than a melting point of said insulating resin;
wherein said insulating resin layer is a film, and in said step (a), the laminate is bonded through pressing on both sides by passing it between at least a pair of laminate rolls.

19. A prepreg with carriers prepared by said process as claimed in claim 1.

20. A process for manufacturing a multilayer-printed circuit board, comprising:
(c) removing at least one carrier of the prepreg with carriers as claimed in claim 19, and
(d) laminating the insulating resin layer in the side where the carrier of said prepreg with carriers is removed and an inner-layer circuit board on which a circuit is formed, and then forming the laminate.

21. The process for manufacturing a multilayer-printed circuit board as claimed in claim 20, wherein said step (d) is conducted while a carrier is present in the opposite side to the side of the prepreg with carriers in which a carrier is removed.

22. A process for continuously manufacturing a thin double-sided plate comprising providing a thin double-sided plate comprising an insulating resin layer containing a backbone material of a textile fabric,
wherein the insulating resin layer containing the backbone material of said textile fabric is prepared by impregnating both sides of the backbone material of said textile fabric with a first and a second insulating resin layers, and said first and said second insulating resin layers are an insulating resin layer with a carrier where the carrier is on the opposite side to the side to be impregnated in the backbone material of said textile fabric, and the insulating resin layer containing the backbone material of said textile fabric has a thickness of 50 μm or less.

23. The process for manufacturing a thin double-sided plate as claimed in claim 22, comprising
(a) laminating the insulating resin layer sides of said first and said second insulating resin layers with a carrier and both sides of the backbone material of said textile fabric, respectively, to form a laminate, and then bonding them under a reduced pressure, and
(b) curing, after said bonding, the insulating resin layer comprising the backbone material of said textile fabric by heating to provide a thin double-sided plate.

24. The process as claimed in claim 23, wherein in said step (a), said laminate is bonded by pressing it from both sides with at least a pair of laminate roll.

25. The process as claimed in claim 24, wherein the insulating resin layer of said laminate is a film.

26. The process for manufacturing a thin double-sided plate as claimed in claim 22, wherein said textile fabric is a glass fabric.

27. The process for manufacturing a thin double-sided plate as claimed in claim 22, wherein said textile fabric has a thickness of 48 μm or less.

28. The process for manufacturing a thin double-sided plate as claimed in claim 22, wherein the insulating resin used for said insulating resin layer is comprised of a resin composition containing a thermosetting resin.

29. The process for manufacturing a thin double-sided plate as claimed in claim 28, wherein said resin composition comprises an epoxy resin.

30. The process for manufacturing a thin double-sided plate as claimed in claim 28, wherein said resin composition comprises a phenol resin.

31. The process for manufacturing a thin double-sided plate as claimed in claim 28, wherein said resin composition comprises a phenoxy resin.

32. The process for manufacturing a thin double-sided plate as claimed in claim 28, wherein said resin composition comprises a cyanate resin and/or prepolymer thereof.

33. The process for manufacturing a thin double-sided plate as claimed in claim 22, wherein said resin composition further comprises an inorganic filler.

34. The process for manufacturing a thin double-sided plate as claimed in claim 33, wherein said inorganic filler is silica.

35. The process for manufacturing a thin double-sided plate as claimed in claim 33, wherein a content of said inorganic filler is equal to or more than 30% by weight and equal to or less than 80% by weight based on the total weight of the resin composition.

36. The process for manufacturing a thin double-sided plate as claimed in claim 22, wherein said carrier comprises a metal foil.

37. The process for manufacturing a thin double-sided plate as claimed in claim 22, wherein said carrier comprises a film sheet whose surface on which the insulating resin layer is to be formed is processed to be peelable.

38. A process for manufacturing a thin double-sided plate,
(a) laminating the insulating resin layer sides of a first and a second insulating resin layers with a carrier and both sides of a backbone material of a textile fabric to form a laminate, and then bonding them under a reduced pressure, and
(b) curing, after said bonding, the insulating resin layer comprising the backbone material of said textile fabric by heating to provide a thin double-sided plate,
wherein said insulating resin layer is a film, and in said step (a), the laminate is bonded through pressing from both sides by passing it between at least a pair of laminate rolls.

39. A thin double-sided plate prepared by the manufacturing process as claimed in claim 22.

40. A multilayer-printed circuit board comprising the thin double-sided plate as claimed in claim 39.
